(19) United States
(12) Patent Application Publication
(10) Pub. No.: US 2024/0200191 A1
(43) Pub. Date: Jun. 20, 2024

(54) BACKSIDE DEPOSITION PREVENTION ON SUBSTRATES

(71) Applicant: LAM RESEARCH CORPORATION, Fremont, CA (US)

(72) Inventors: Christopher GAGE, Truckee, CA (US); Ramesh CHANDRASEKHARAN, Lake Oswego, OR (US); Eric H. LENZ, Livemore, CA (US); Karl Frederick LEESER, West Linn, OR (US)

(21) Appl. No.: 18/287,372

(22) PCT Filed: Apr. 15, 2022
(86) PCT No.: PCT/US2022/024938

§ 371 Date: Oct. 18, 2023

Related U.S. Application Data
(60) Provisional application No. 63/177,617, filed on Apr. 21, 2021.

(51) Int. Cl. C23C 16/458; C23C 16/04; C23C 16/455

(52) U.S. Cl. CPC C23C 16/4585; C23C 16/04; C23C 16/45521; C23C 16/45565; C23C 16/4586

(57) ABSTRACT

Various systems and methods are provided to prevent backside deposition on a substrate by using a combination of approaches. The approaches include clamping the substrate to a pedestal and/or supplying purge gases to an area where deposition is not desired. The clamping methods include electrostatic or vacuum clamping. In addition, various pedestal and edge ring designs are provided for supplying purge gases to the area where deposition is not desired. The use of clamping in conjunction with purging can further enhance the performance without affecting deposition of materials on front side of the substrate. The clamping along the edge of the substrate can be made more effective by machining an upper surface of the pedestal to have a slight dish or dome like shape (i.e., concave or convex, respectively).

### CROSS-REFERENCE TO RELATED APPLICATIONS

This application claims the benefit of U.S. Provisional Application No. 63/177,617, filed on Apr. 21, 2021. The entire disclosure of the application referenced above is incorporated herein by reference.

### FIELD

The present disclosure relates generally to substrate processing systems and more particularly to systems and methods for preventing backside deposition on substrates.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. ALD is typically performed in a heated processing chamber. The processing chamber is maintained at a sub-atmospheric pressure using a vacuum pump and a controlled flow of an inert gas. The substrate to be coated with a film is placed in the processing chamber and is allowed to equilibrate with the temperature of the processing chamber before starting the ALD process.

### SUMMARY

A system comprises a pedestal arranged below a showerhead. The pedestal includes a base portion and a stem portion. The base portion supports a substrate. The base portion is disc shaped and has an annular recess on an upper surface of the base portion along an outer diameter of the base portion. The stem portion is connected to the base portion. The system comprises a heat shield arranged below a lower surface of the base portion. The heat shield and the lower surface define a manifold that is in fluid communication with a gas inlet. The system comprises an edge ring including a cylindrical portion and an annular portion. The cylindrical portion surrounds the base portion. The cylindrical portion has a first end resting on an outer edge of the heat shield and has a second end. An inner surface of the cylindrical portion and an outer surface of the base portion define a first gap in fluid communication with the manifold. The annular portion extends radially inwards over the annular recess from the second end of the cylindrical portion. The annular portion and the annular recess define a second gap in fluid communication with the first gap. A purge gas supplied to the gas inlet flows through the manifold, the first and second gaps, and radially outwards over the annular portion.

In other features, the purge gas is supplied to the gas inlet while a material is deposited from the showerhead on a showerhead-facing surface of the substrate, and the purge gas prevents the material from depositing on a pedestal-facing surface of the substrate.

In another feature, the pedestal includes an electrostatic clamping system to clamp the substrate to the upper surface of the base portion.

In another feature, the pedestal includes a vacuum clamping system to clamp the substrate to the upper surface of the base portion.

In another feature, the upper surface of the base portion lies in a higher plane at an outer diameter of the base portion than at a center of the base portion.

In another feature, the upper surface of the base portion lies in a lower plane at an outer diameter of the base portion than at a center of the base portion.

In another feature, the system further comprises an annular sealing band arranged on the upper surface of the base portion. An outer diameter of the annular sealing band is equal to an inner diameter of the annular recess and an outer diameter of the substrate.

In another feature, the system further comprises an actuator configured to move the pedestal vertically relative to the showerhead to adjust a gap between the substrate and the showerhead during processing.

In another feature, an upper surface of the annular portion lies in a higher plane than a showerhead-facing surface of the substrate.

In other features, each of upper and lower surfaces of the annular portion includes a radially outer portion and a radially inner portion. The radially outer portions extend parallel to the annular recess from the cylindrical portion, and the radially inner portions slope towards an inner diameter of the annular portion.

In other features, the cylindrical portion is parallel to the outer surface of the base portion, and the annular portion is parallel to the annular recess.

In another feature, outer diameters of the cylindrical and annular portions are equal.

In another feature, an inner diameter of the annular recess is greater than or equal to an outer diameter of the substrate.

In another feature, an inner diameter of the annular portion is greater than an inner diameter of the annular recess and an outer diameter of the substrate.

In other features, an upper surface of the annular portion is level with a showerhead-facing surface of the substrate. A lower surface of the annular portion extends parallel to the annular recess from the cylindrical portion and slopes upwards towards an inner diameter of the annular portion.

In other features, the system further comprises a second ring arranged at a distance above the upper surface of the annular portion. Inner and outer diameters of the second ring are equal to respective diameters of the annular portion. Upper and lower surfaces of the second ring are parallel to the upper surface of the annular portion.

In another feature, the annular portion includes a plurality of holes extending radially outwards from an inner diameter of the annular portion.

In other features, a lower surface of the annular portion extends parallel to the annular recess from the cylindrical portion and slopes upwards towards an inner diameter of the annular portion. An upper surface of the annular portion includes a first portion that slopes upwards from the inner diameter of the annular portion for a first distance and a second portion that slopes downwards towards from the first distance to an outer diameter of the annular portion. The upper surface of the annular portion includes a plurality of holes extending radially through the first portion and partially through second portion.

In another feature, the system further comprises a controller to control flow of the purge gas through the gas inlet.

In another feature, the gas inlet is located at a bottom of the stem portion.

In still other features, a pedestal to support a substrate arranged below a showerhead comprises a base portion having a disc shape and a stem portion extending from the base portion. The base portion includes an annular ridge on an upper surface, an annular protrusion on a lower surface, and a plurality of holes extending outwardly from the lower surface to the upper surface. The annular ridge has an outer diameter less than an outer diameter of the base portion and has an inner diameter greater than or equal to an outer diameter of the substrate. The annular protrusion has a diameter less than the inner diameter of the annular ridge and the outer diameter of the substrate. The holes are arranged along a first circle on the upper surface and along a second circle on the lower surface. The first circle has a first diameter that is less than the inner diameter of the annular ridge and the outer diameter of the substrate and greater than the diameter of the annular protrusion. The second circle has a second diameter that is less than the diameter of the annular protrusion.

In other features, a system comprises the pedestal, a heat shield arranged parallel to and below the lower surface of the base portion, and a gas source. The heat shield is connected to the annular protrusion. The heat shield, the lower surface, and the annular protrusion define a manifold that is in fluid communication with a gas inlet. The gas source supplies a purge gas to the gas inlet while a material is deposited from the showerhead on a showerhead-facing surface of the substrate. The purge gas flows through the manifold and the holes, flows radially outwards over the annular ridge, and prevents the material from depositing on a pedestal-facing surface of the substrate.

In another feature, the pedestal further comprises an electrostatic clamping system or a vacuum clamping system to clamp the substrate to the upper surface of the base portion.

In another feature, the annular ridge ascends vertically from the upper surface of the base portion at the inner diameter of the annular ridge, extends outwards at an angle relative to a vertical axis of the stem portion, extends radially outwards, and descends vertically to the upper surface of the base portion at the outer diameter of the annular ridge.

In another feature, the holes extend from the lower surface to the upper surface at an acute angle relative to a vertical axis of the stem portion.

In another feature, the pedestal further comprises an annular sealing band arranged on the upper surface of the base portion. An outer diameter of the annular sealing band is less than the first diameter of the first circle.

In another feature, the pedestal further comprises an actuator configured to move the pedestal vertically relative to the showerhead to adjust a gap between the substrate and the showerhead during processing.

In another feature, the system further comprises a controller to control flow of the purge gas through the gas inlet.

In another feature, the gas inlet is located at a bottom of the stem portion.

In other features, the system further comprises a ring arranged around the pedestal. The ring includes a cylindrical portion surrounding the base portion and having a first end aligned with an outer edge of the heat shield and a second end. The ring includes an annular portion extending radially inwards from the second end over the upper surface of the base portion to the outer diameter of the annular ridge. Upper surfaces of the annular ridge and the annular portion of the ring are coplanar.

In still other features, a pedestal assembly comprises a pedestal including a base plate having a first surface and a second surface opposite the first surface, and including a stem extending from the second surface of the base plate. A plurality of through holes extend from the first surface through the second surface of the base plate at a location radially outside of the stem. The pedestal includes a collar arranged around the stem and the plurality of through holes. The collar defines a first annular volume between an inner surface of the collar and an outer surface of the stem. An upper surface of the collar forms a surface-to-surface seal with the second surface of the base plate. The pedestal assembly comprises an annular heat shield having a first portion arranged below the second surface of the base plate and having a second portion extending from a radially inner end of the first portion. The second portion surrounds the collar and defines a second annular volume between an inner surface of the second portion of the annular heat shield and an outer surface of the collar.

In another feature, the first annular volume is separate from the second annular volume.

In another feature, one or more gases are suctioned out from under a substrate placed on the base plate via the plurality of through holes and the first annular volume to clamp the substrate to the base plate.

In another feature, a purge gas is injected into the second annular volume to egress around edges of a substrate placed on the base plate during processing.

In another feature, the purge gas prevents deposition on a pedestal-facing surface of the substrate.

In other features, the pedestal assembly further comprises an edge ring surrounding the base plate. A bottom surface of the edge ring forms a surface-to-surface seal with an upper surface of the first portion of the annular heat shield. The upper surface of the first portion of the annular heat shield, an inner side surface of the edge ring, and the second surface of the base plate define a manifold that is in fluid communication with the second annular volume. A purge gas is injected into the second annular volume to egress through a gap between the edge ring and the base plate.

In another feature, the purge gas prevents deposition on a pedestal-facing surface of a substrate arranged on the base plate.

In other features, a bottom end of the stem of the pedestal includes a flange extending radially outwardly. The pedestal assembly further comprises a pedestal support structure attached to the flange with an O-ring disposed between the flange and the pedestal support structure.

In another feature, the pedestal support structure includes a cylindrical body with a side wall, a vertical bore in the side wall defines a gas channel, and the gas channel fluidly communicates with the first annular volume and the plurality of through holes.

In another feature, the pedestal support structure includes a cylindrical body with a side wall, a bore in the side wall defines a gas channel, and the gas channel fluidly communicates with the second annular volume.

In other features, the pedestal support structure includes a cylindrical body defining an inner cavity and includes a second flange extending radially outwardly from an upper surface of the cylindrical body. The pedestal assembly further comprises one or more clamps connecting the flange at the bottom end of the stem to the second flange of the pedestal support structure.

In other features, the pedestal support structure includes a cylindrical body defining an inner cavity and includes a second flange extending radially outwardly from an upper surface of the cylindrical body. The pedestal assembly further comprises a clamp having an L-shaped cross-section. The second flange rests on a horizontal portion of the clamp forming a surface-to-surface seal therewith.

In another feature, an upper end of a vertical portion of the clamp includes a third flange extending radially outwardly and includes first and second vertical portions respectively extending from radially outer and inner ends on an upper surface of the third flange.

In other features, a bottom end of the collar forms a first surface-to-surface seal with the second vertical portion, and a bottom end of the second portion of the annular heat shield forms a second surface-to-surface seal with the first vertical portion.

In another feature, the first and second surface-to-surface seals prevent fluid communication between the first and second annular volumes.

In other features, the cylindrical body includes a vertical portion extending upwards from the second flange. A radially inner portion of the upper end of the vertical portion of the clamp forms a surface-to-surface seal with a radially outer surface of an upper end of the vertical portion of the cylindrical body.

In other features, the cylindrical body has a side wall having a first bore therein. The vertical portion of the clamp is spaced from the vertical portion of the cylindrical body extending upwards from the second flange defining a cavity that is in fluid communication with the first bore. The upper end of the vertical portion of the clamp includes a second bore that is in fluid communication with the cavity and the second annular volume.

In other features, the pedestal assembly further comprises a valve and a controller. The valve is configured to selectively connect the gas channel, the first annular volume, and the plurality of through holes to a vacuum pump. The controller is configured to selectively control the valve to remove one or more gases from under a substrate arranged on the base plate via the gas channel, the first annular volume, and the plurality of through holes to clamp the substrate to the base plate during processing of the substrate.

In other features, the pedestal assembly further comprises a valve and a controller. The valve is configured to selectively connect the gas channel and the second annular volume to a source of a purge gas. The controller is configured to selectively control the valve to supply the purge gas through the gas channel and the second annular volume during processing of a substrate arranged on the base plate to prevent deposition on a pedestal facing side of the substrate.

In other features, the pedestal assembly further comprises an annular seal band disposed on the first surface of the base plate along an outer diameter of the first surface. The pedestal assembly further comprises a plurality of projections extending upwards from the first surface of the base plate. The projections are distributed from a center of the first surface to an inner diameter of the annular seal band.

In another feature, a height of the projections decreases from the inner diameter of the annular seal band to the center of the first surface of the base plate.

In another feature, a height of the projections increases from the inner diameter of the annular seal band to the center of the first surface of the base plate.

In still other features, a pedestal assembly comprises a pedestal including a base plate and a stem extending from the base plate. The base plate is disc shaped and has an upper surface. The pedestal assembly comprises a plurality of projections extending upwards from the upper surface of the base plate and distributed from a center of the upper surface of the base plate to an outer diameter of the pedestal. The projections have a height tailored to tune a conductive heat transfer proximate to the projections.

In another feature, the projections have a profile defined by upper ends of the projections.

In another feature, the projections have equal height.

In another feature, a first set of the projections has a different height than a second set of the projections.

In another feature, a height of the projections decreases from the inner diameter of the annular seal band to the center of the upper surface of the base plate.

In another feature, a height of the projections increases from the inner diameter of the annular seal band to the center of the upper surface of the base plate.

In another feature, the projections are cylindrical.

In another feature, the pedestal assembly further comprises an electrostatic clamping system disposed in the pedestal to clamp a substrate to the upper surface of the base plate.

In another feature, the pedestal assembly further comprises a vacuum clamping system disposed in the pedestal to clamp a substrate to the upper surface of the base plate.

In another feature, a substrate is not clamped to the upper surface of the base plate.

In another feature, a height of the projections changes linearly from one radial edge to an opposite radial edge of the upper surface of the base plate.

In another feature, the upper surface of the base plate including the projections is concave.

In another feature, the upper surface of the base plate including the projections is convex.

In still other features, a pedestal assembly comprises a pedestal including a base plate and a stem extending from the base plate. The base plate is disc shaped and has an upper surface that is concave. The pedestal assembly comprises a plurality of projections extending upwards from the upper surface of the base plate and distributed from a center of the upper surface of the base plate to an outer diameter of the pedestal.

The projections have top ends that are concave.

In another feature, radii of curvature of the upper surface of the pedestal and the top ends of the projections are equal.

In another feature, radii of curvature of the upper surface of the pedestal and the top ends of the projections are different.

In another feature, a first radius of curvature of the upper surface of the pedestal is greater than a second radius of curvature of the top ends of the projections.

In another feature, a first radius of curvature of the upper surface of the pedestal is less than a second radius of curvature of the top ends of the projections.

In still other features, a pedestal assembly comprises a pedestal including a base plate and a stem extending from the base plate. The base plate is disc shaped and has an upper surface that is convex. The pedestal assembly comprises a plurality of projections extending upwards from the upper surface of the base plate and distributed from a center of the upper surface of the base plate to an outer diameter of the pedestal. The projections have top ends that are convex.

In another feature, radii of curvature of the upper surface of the pedestal and the top ends of the projections are equal.

In another feature, radii of curvature of the upper surface of the pedestal and the top ends of the projections are different.

In another feature, a first radius of curvature of the upper surface of the pedestal is greater than a second radius of curvature of the top ends of the projections.

In another feature, a first radius of curvature of the upper surface of the pedestal is less than a second radius of curvature of the top ends of the projections.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1A and 1B show examples of a substrate processing system comprising a processing chamber including a pedestal and an edge ring designed to prevent backside deposition on substrates according to the present disclosure;

FIG. 2 is a perspective cross-sectional view of a pedestal that can be used with any of the edge rings shown in FIGS. 3-6 to prevent backside deposition on substrates according to the present disclosure;

FIG. 3 is a perspective cross-sectional view of an edge ring that can be used with the pedestal of FIG. 2 to prevent backside deposition on substrates according to the present disclosure;

FIG. 4 is a perspective cross-sectional view of another edge ring that can be used with the pedestal of FIG. 2 to prevent backside deposition on substrates according to the present disclosure;

FIG. 5A is a perspective cross-sectional view of an edge ring including holes that can be used with the pedestal of FIG. 2 to prevent backside deposition on substrates according to the present disclosure;

FIGS. 5B and 5C show additional views of the holes in the edge ring of the FIG. 5A in further detail;

FIG. 6 is a perspective cross-sectional view of another edge ring that can be used with the pedestal of FIG. 2 to prevent backside deposition on substrates according to the present disclosure;

FIGS. 7A-7C show perspective and side cross-sectional views of a pedestal including holes that can supply a purge gas from under a substrate to prevent backside deposition according to the present disclosure;

FIG. 8 shows a method for preventing backside deposition on substrates according to the present disclosure;

FIGS. 9A and 9B show an example of a pedestal including a vacuum clamping system and also supplying a purge gas from under a substrate to prevent backside deposition according to the present disclosure;

FIGS. 10A-10C show an example of projections (mesas) arranged on a pedestal to improve clamping force on a substrate during processing according to the present disclosure; and

FIGS. 11A-12E show various configurations in which the mesas can be arranged on the pedestal.

In the drawings, reference numbers may be reused to identify similar and/or identical elements.

### DETAILED DESCRIPTION

Backside deposition prevention while depositing materials (e.g., metal films) on substrates (e.g., semiconductor wafers) can be a critical performance metric. Modern deposition techniques such as atomic layer deposition (ALD) and plasma enhanced chemical vapor deposition (PECVD) have a relatively higher conformal performance. Therefore, it has become increasingly challenging to prevent deposition where it is not desired (e.g., on the backside of a substrate) while depositing materials on the front side of the substrate.

The present disclosure provides systems and methods to prevent backside deposition by using a combination of approaches. The approaches include clamping the substrate to a pedestal and/or supplying purge gases to an area where deposition is not desired. The clamping methods include electrostatic or vacuum clamping. In addition, various pedestal and edge ring designs are provided for supplying purge gases to the area where deposition is not desired. The use of clamping in conjunction with purging can further enhance the performance without affecting deposition of materials on the front side of the substrate.

Specifically, viscous flow of deposition chemistries to the backside of the substrate can be readily prevented by placing the substrate on a highly polished (i.e., smooth) surface on a pedestal (e.g., a sealing band). Placing the substrate on a highly polished surface allows only molecular flow to the backside of the substrate. Allowing only molecular flow to the backside of the substrate can be adequate in some applications to prevent the backside deposition to a desired level. By purging a bevel area of the substrate or the backside of the substrate, with gaps between the substrate and an edge ring that can sustain viscous flow, a reduction in concentration of deposition chemistries in the bevel area can be achieved. With enough viscous flow in a gap having a predetermined size, the concentration of these chemistries can be reduced in the bevel area to a level that does not sustain deposition on the backside of the substrate. Other approaches include using a deposition inhibitor, or using either inert chemistries or reactive chemistries that react with precursors before the precursors can adhere to the substrate surface.

The above approaches are most effective when the substrate is clamped to the pedestal surface with a substantial force (e.g., 50× the weight of the substrate). Clamping methods can include using a pressure differential (i.e., vacuum clamping) or electrostatic clamping (e.g., an electrostatic chuck or ESC). The clamping along the edge of the substrate can be made more effective by machining an upper surface of the pedestal to have a slight dish or dome like shape. That is, the upper surface of the pedestal can be machined to be slightly concave or convex. Due to the curved shaping, the edge portion of the pedestal is either slightly higher (in case of dish shape) or lower (in case of dome shape) than the center portion of the pedestal. The curved shaping significantly improves clamping along the edge of the substrate. The improved clamping along the edge of the substrate further prevents backside deposition on substrates.

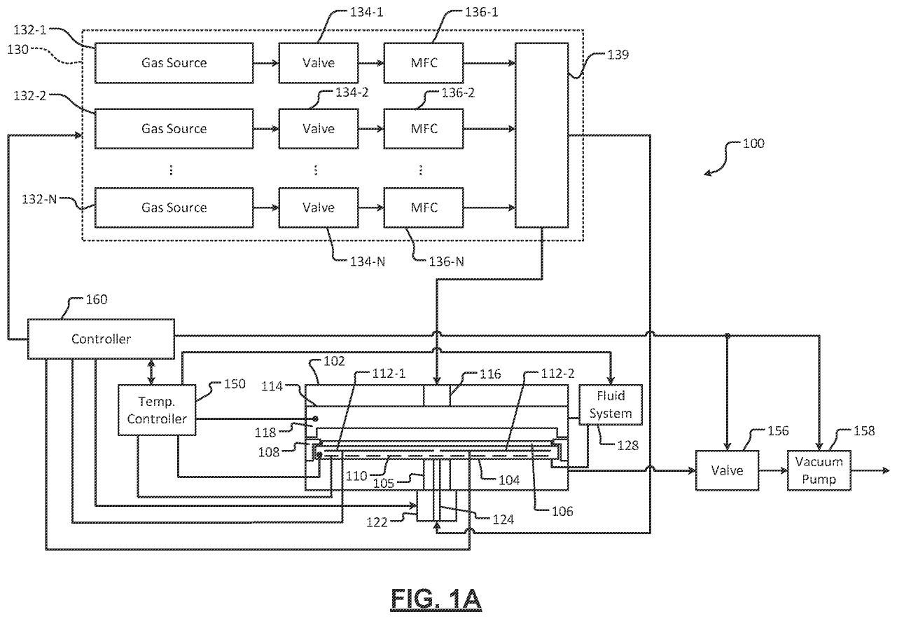

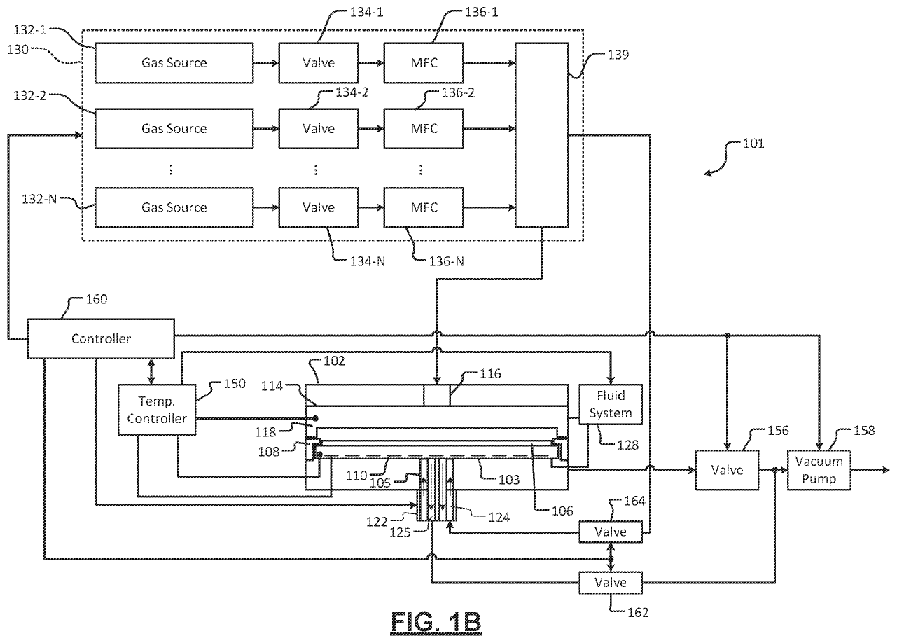

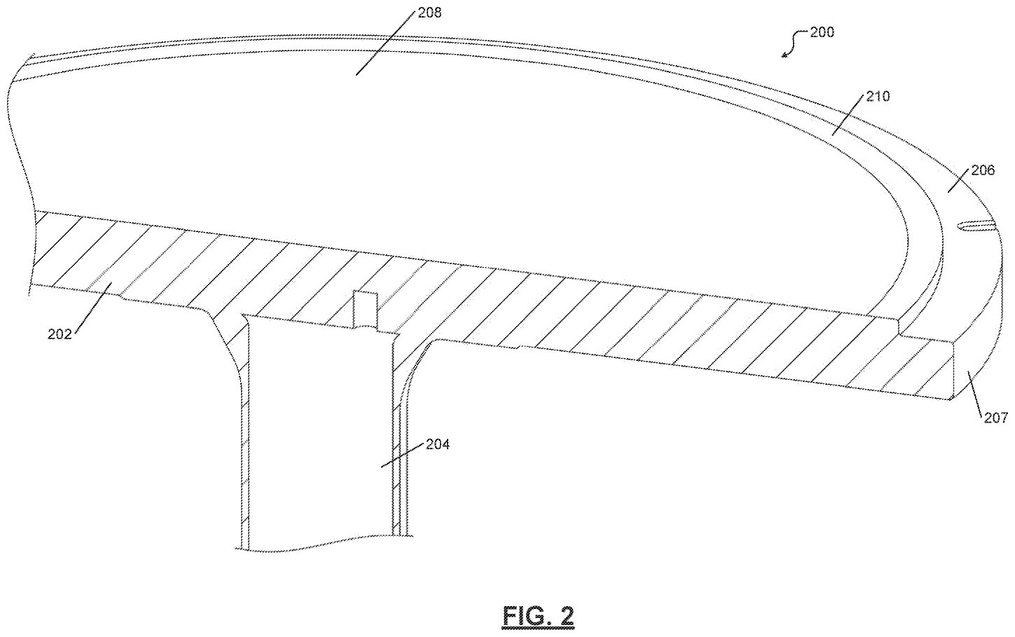

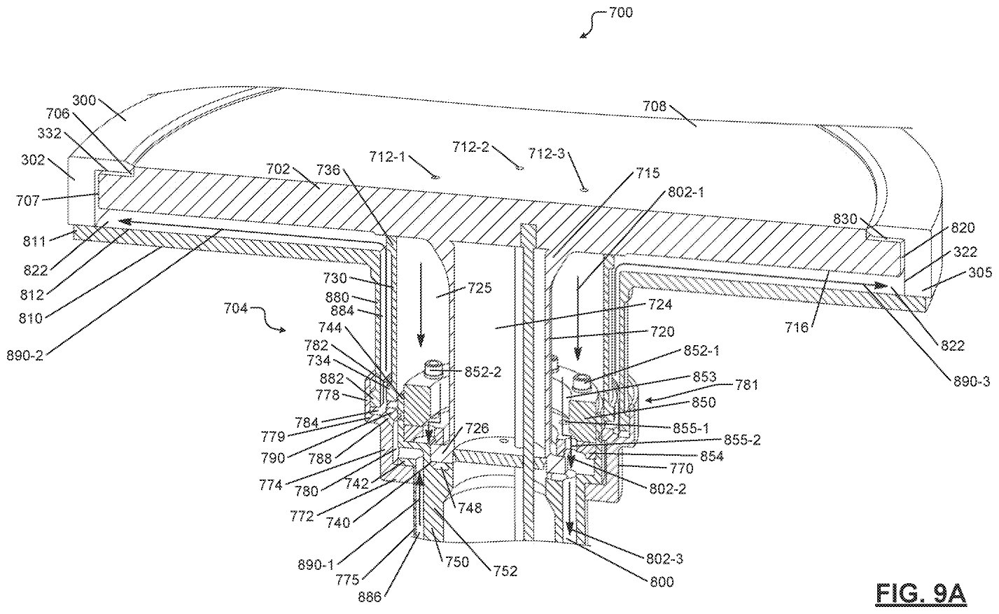

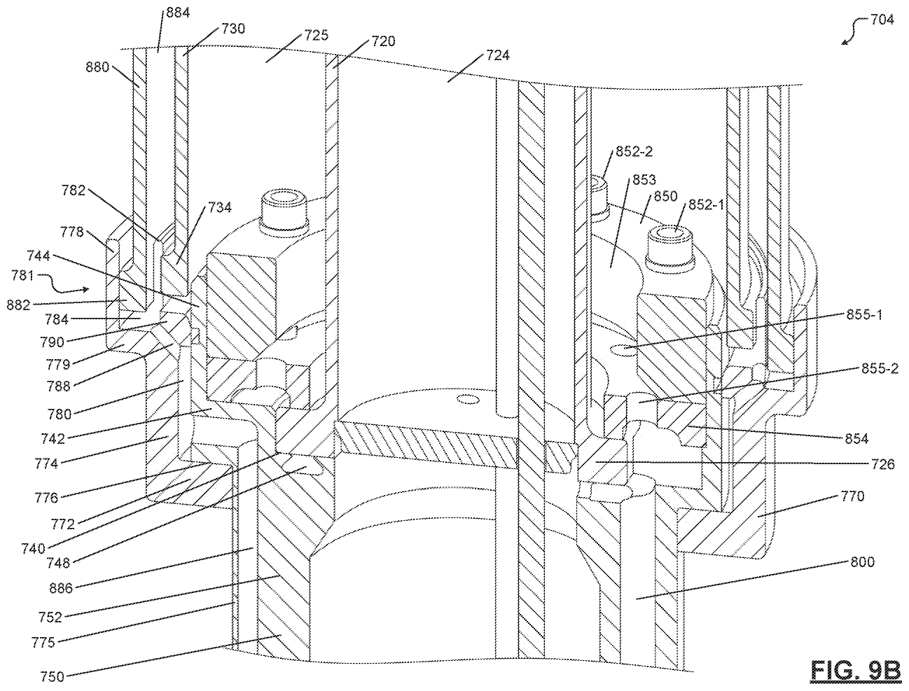

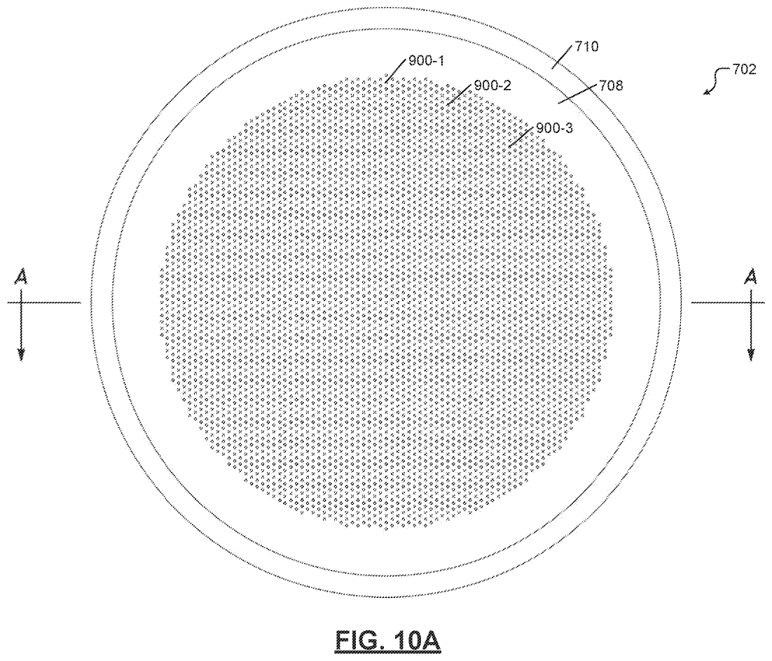

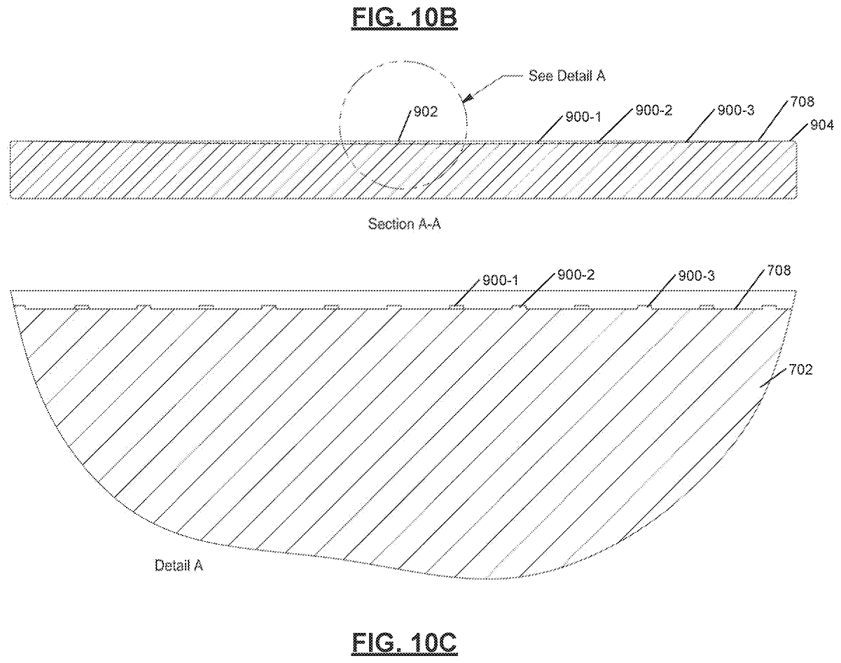

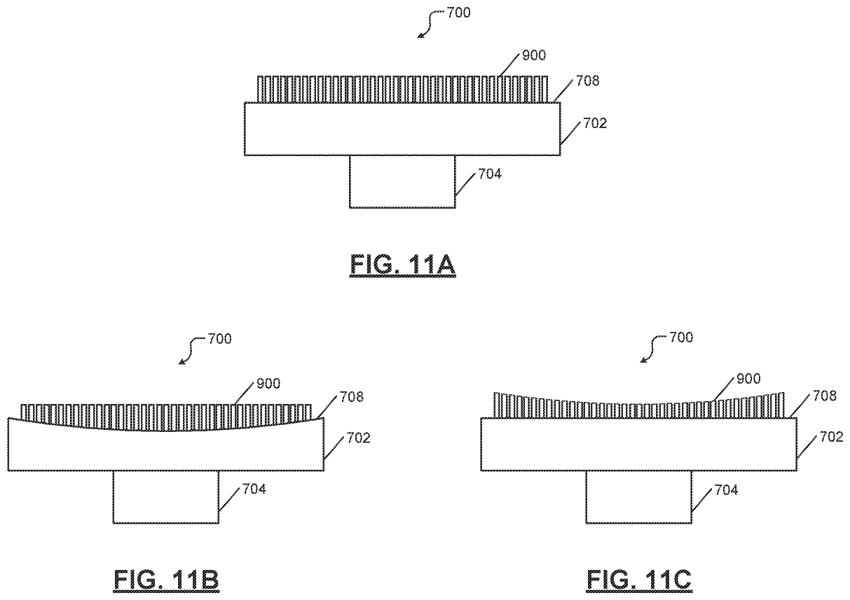

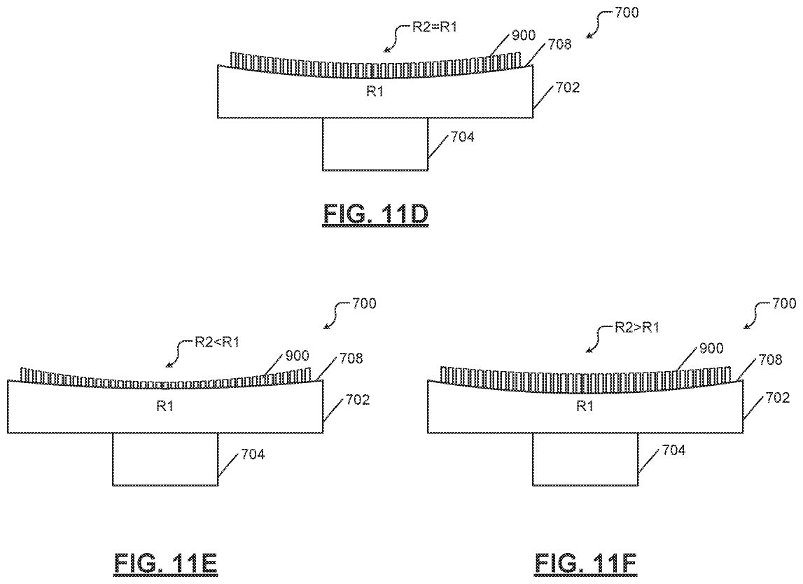

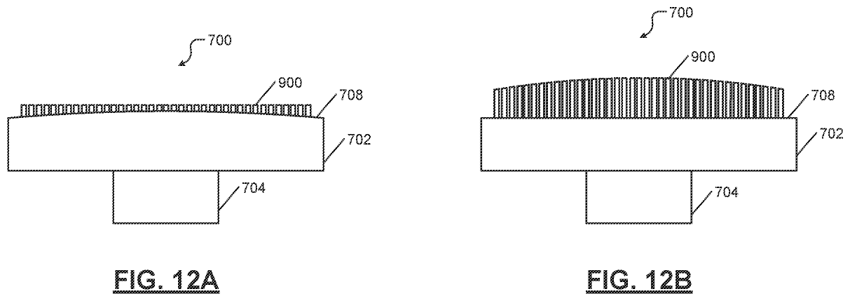

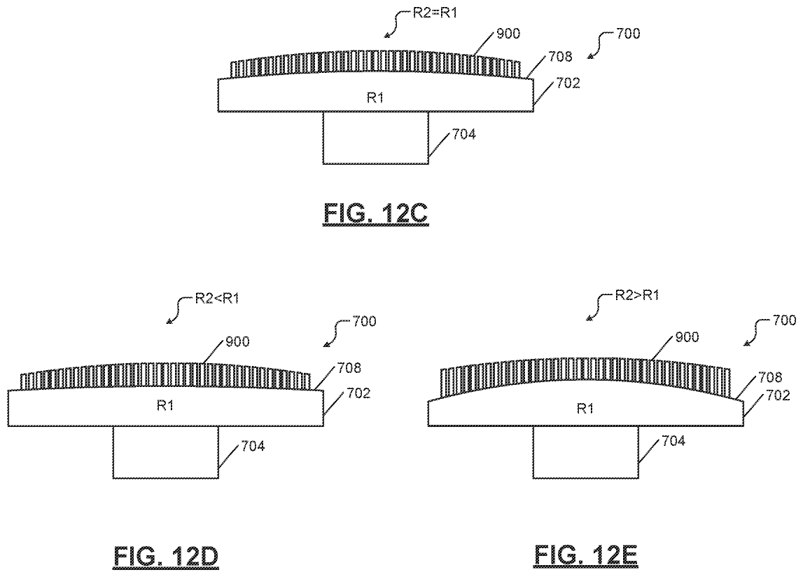

The present disclosure is organized as follows. Initially, a substrate processing system comprising a processing chamber that can utilize a pedestal and an edge ring designed to prevent backside deposition is shown and described with reference to FIGS. 1A and 1B. FIG. 1A shows use of electrostatic clamping. FIG. 1B shows use of vacuum clamping. Subsequently, various designs of the pedestal and the edge rings are shown and described in detail with reference to FIGS. 2-7C. A method for preventing backside deposition is shown and described with reference to FIG. 8. Vacuum clamping is shown and described in detail with reference to FIGS. 9A and 9B. The curved shaping of the upper surface of a pedestal is shown and described with reference to FIGS. 10A-10C. Various configurations in which projections (mesas) can be arranged on the upper surface of the pedestal are shown and described with reference to FIGS. 11A-12E.

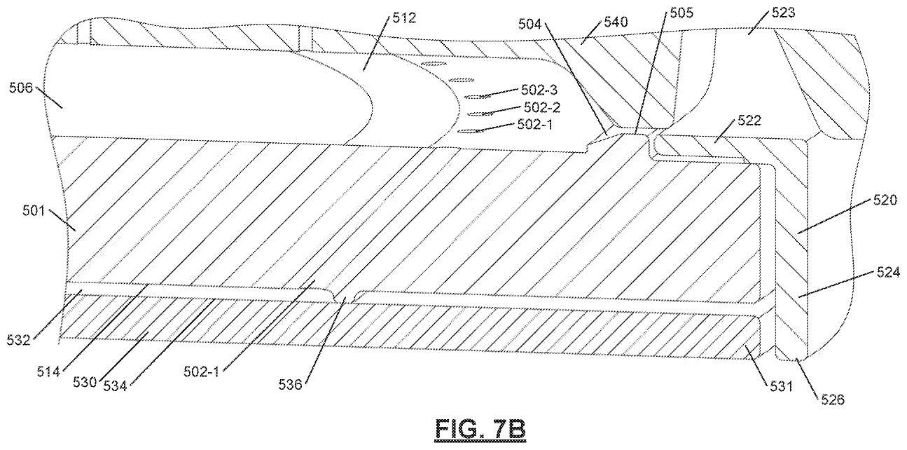

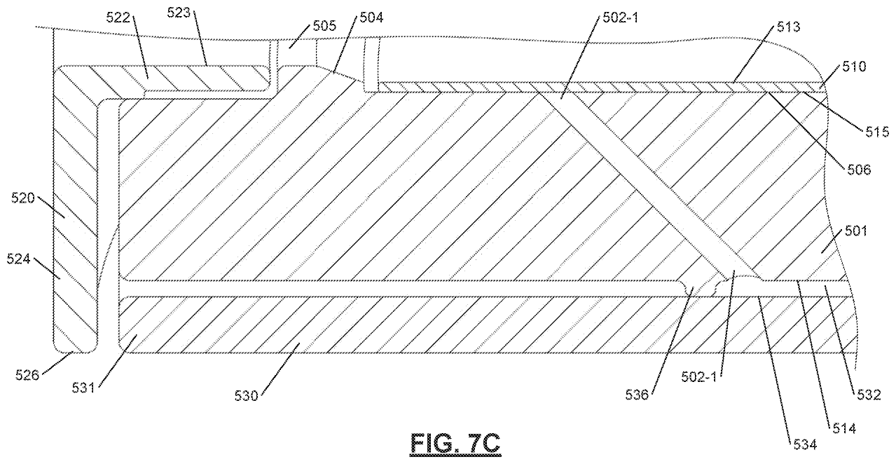

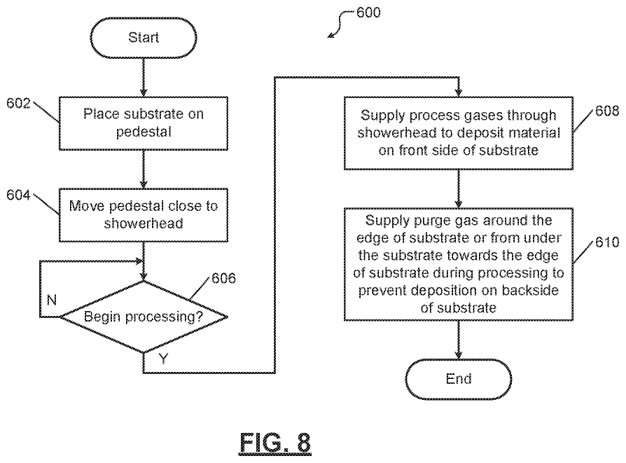

FIG. 1A shows an example of a substrate processing system 100 comprising a processing chamber 102 configured to process a substrate (e.g., using ALD). The processing chamber 102 comprises a substrate support (e.g., a pedestal) 104. The pedestal 104 is made of a ceramic material to withstand relatively high process temperatures. For example, the process temperatures can be greater than 600 degrees Celsius. Examples of the pedestal 104 are shown in further detail in FIGS. 2 and 7A-7C.

During processing, a substrate 106 is arranged on an upper surface of the pedestal 104. The substrate 106 may be clamped to the upper surface of the pedestal 104 using electrostatic clamping employed by the pedestal 104. For example, one or more clamping electrodes 112-1, 112-2 (collectively the clamping electrodes 112) may be disposed in the pedestal 104. The clamping electrodes 112 clamp the substrate 106 to the upper surface of the pedestal 104 using an electrostatic force.

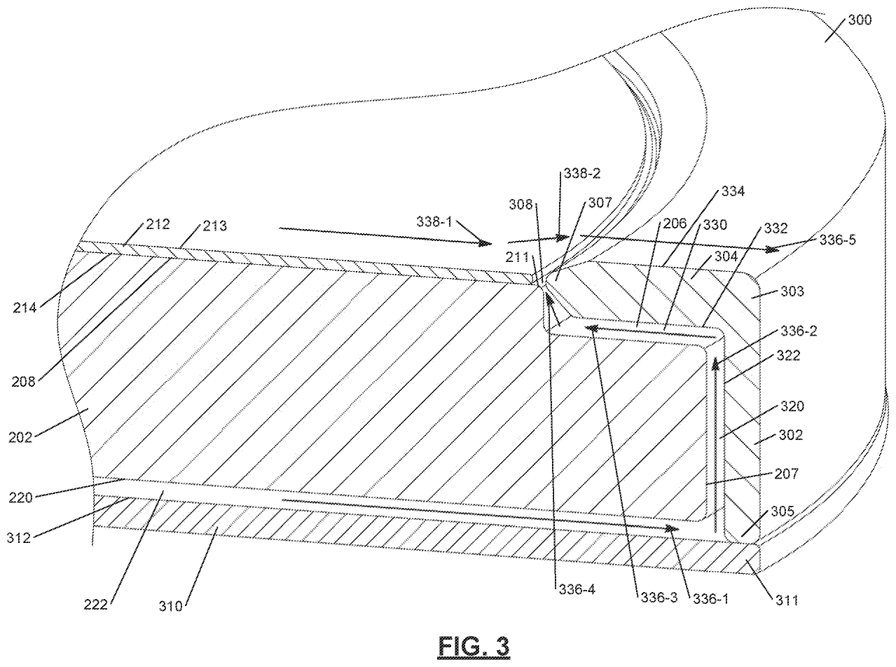

An edge ring 108 is arranged around the upper surface of the pedestal 104 and the substrate 106. The edge ring 108 may include any of the edge rings shown in FIGS. 3-6. The edge ring 108 is also made of a ceramic material that can withstand relatively high process temperatures, which can be greater than 600 degrees Celsius.

One or more heaters 110 (e.g., a heater array, zone heaters, etc.) are disposed in the pedestal 104 to heat the substrate 106 during processing. Additionally, while not shown, a cooling system comprising cooling channels through which a coolant can flow to cool the pedestal 104 may be disposed in the pedestal 104. Additionally, while not shown, one or more temperature sensors are disposed in the pedestal 104 to sense the temperature of the pedestal 104. While the clamping electrodes 112 are shown as being arranged above the heaters 110, the clamping electrodes 112 and the heaters 110 may be arranged in the pedestal 104 in other ways.

Additionally, a fluid delivery system 128 supplies a coolant to a cooling system (e.g., comprising a plurality of cooling channels, not shown) in the pedestal 104. The fluid system 128 generally will not flow the coolant through the pedestal 104 for relatively high temperature processes (e.g., process temperatures greater than 600 degrees Celsius). For some relatively low temperature processes (e.g., process temperatures less than 300 degrees Celsius) the pedestal 104 may use a liquid inside the pedestal 104 as a ballast to make up for lower thermal energy losses.

The processing chamber 102 further comprises a gas distribution device 114 such as a showerhead to introduce and distribute process gases into the processing chamber 102. The gas distribution device (hereinafter showerhead) 114 may include a stem portion 116 including one end connected to a top surface of the processing chamber 102. A base portion 118 of the showerhead 114 is generally cylindrical and extends radially outwardly from an opposite end of the stem portion 116 at a location that is spaced from the top surface of the processing chamber 102.

A substrate-facing surface of the base portion 118 of the showerhead 114 comprises a ceramic faceplate 120. The ceramic faceplate 120 comprises a plurality of outlets or features (e.g., slots or through holes) through which process gases flow into the processing chamber 102. While not shown, the showerhead 114 also comprises heating and cooling plates that respectively include one or more heaters and cooling channels. Further, while not shown, one or more temperature sensors may be disposed in the showerhead 114 to sense the temperature of the showerhead 114. The fluid delivery system 128 supplies a coolant to the cooling channels in the showerhead 114.

An actuator 122 moves the pedestal 104 vertically relative to the showerhead 114, which is stationary. By vertically moving the pedestal 104 relative to the showerhead 114 using the actuator 122, a gap between the showerhead 114 and the pedestal 104 (and therefore a gap between the substrate 106 and the ceramic faceplate 120 of the showerhead 114) can be varied. The gap can be varied dynamically during a process or between processes performed on the substrate 106. During processing, the ceramic faceplate 120 of the showerhead 114 is closer to the pedestal 104 than shown.

A gas delivery system 130 comprises one or more gas sources 132-1, 132-2, . . . , and 132-N (collectively gas sources 132), where N is an integer greater than 1. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 139. An output of the manifold 139 is fed to the processing chamber 102.

The gas sources 132 may supply process gases, cleaning gases, purge gases, inert gases, and so on to the processing chamber 102. One of the gas sources 132 supplies a purge gas through a gas inlet (hereinafter the inlet) 124 at the bottom of the pedestal 104. As shown and described below in detail with reference to FIGS. 2-7C, the purge gas from the inlet 124 flows through a stem portion 105 of the pedestal 104. In one example, the purge gas flows through a manifold under the pedestal 104 and a gap between the edge of the pedestal 104 and the edge ring 108 as shown and described below in detail with reference to FIGS. 2-6. Alternatively, the purge gas flows via through holes in the pedestal 104 as shown and described below in detail with reference to FIGS. 7A-7C. In either example, the purge gas prevents deposition on the backside of the substrate 106.

A temperature controller 150 is connected to the heaters 110 and temperature sensors in the pedestal 104, to the heaters and temperature sensors in the showerhead 114, and to the fluid delivery system 128. The temperature controller 150 controls power supplied to the heaters 110 and coolant flow through the cooling system in the pedestal 104 to control the temperature of the pedestal 104 and the substrate 106. The temperature controller 150 also controls power supplied to the heaters in the showerhead 114 and coolant flow through the cooling channel in the showerhead 114 to control the temperature of the showerhead 114.

A valve 156 is connected to an exhaust port of the processing chamber 102 and to the vacuum pump 158. A vacuum pump 158 maintains sub-atmospheric pressure inside the processing chamber 102 during substrate processing. The valve 156 and the vacuum pump 158 are used to control pressure in the processing chamber 102 and to evacuate exhaust gases and reactants from the processing chamber 102. A system controller 160 controls the components of the substrate processing system 100.

FIG. 1B shows a substrate processing system 101 where a pedestal 103 employs vacuum clamping instead of electrostatic clamping. The substrate processing system 101 shown in FIG. 1B is identical to the substrate processing system 100 shown in FIG. 1A except for the following. In the substrate processing system 101, the pedestal 103 uses vacuum clamping instead of electrostatic clamping. Accordingly, the clamping electrodes 112 are not used in the pedestal 103. The pedestal 103 is shown and described in detail with reference to FIGS. 9A-9B.

Briefly, the pedestal 103 includes an annular volume 125 in the stem portion 105. The annular volume 125 is in fluid communication with a plurality of gas through holes in the upper surface of the pedestal 103, which are shown and described in detail with reference to FIGS. 9A-9B. The annular volume 125 is in fluid communication with the vacuum pump 158 through a valve 162. The system controller 160 controls the valve 162.

During processing, the vacuum pump 158 creates a vacuum under the substrate 106 by suctioning gases from under the substrate 106 through the plurality of through holes in the upper surface of the pedestal 103. The vacuum pump 158 removes the gases from under the substrate 106 through the annular volume 125 and the valve 162. The vacuum created by the vacuum pump 158 clamps the substrate 106 to the upper surface of the pedestal 103.

The inlet 124 through which the purge gas is supplied to the pedestal 103 is shown and described in further detail with reference to FIGS. 9A-9B. Briefly, the inlet 124 is also annular in shape and surrounds the annular volume 125. The inlet 124 is not in fluid communication with the annular volume 125. The inlet 124 is connected to the manifold 139 through a valve 164. The system controller 160 controls the valve 164. The purge gas flows through a gap between the edge of the pedestal 103 and the edge ring 108. Alternatively, the purge gas flows via through holes in the pedestal 103. The purge gas prevents deposition on the backside of the substrate 106 as described above with reference to FIG. 1A and as described in further detail below with reference to FIGS. 3-6. These and other features of the vacuum clamping used in the pedestal 103 are described below in greater detail with reference to FIGS. 9A-9B.

Below are various designs of the pedestal and the edge rings that can be arranged around the pedestal and the substrate in a processing chamber (e.g., the processing chamber 102 shown in FIGS. 1A and 1B). For illustrative purposes, only partial views of the pedestals are shown in FIGS. 2, 7A-7C, and 9A. However, it is understood that the top surface of the pedestals on which the substrate is arranged during processing is generally circular in shape. Further, it is understood that the top surface of the pedestals additionally has other structural and geometric details as shown and described below. Also, for illustrative purposes, only partial views of the edge rings are shown in FIGS. 3-6. However, it is understood that the edge rings are generally annular in shape. Further, it is understood that the edge rings additionally have other structural and geometric details as shown and described below.

FIG. 2 shows an example of a pedestal 200 according to the present disclosure. Any of the edge rings shown in FIGS. 3-6 can be used with the pedestal 200 to prevent backside deposition as described below. The pedestal 200 includes a base portion 202 and a stem portion 204. In some examples, the base portion 202 is disc shaped, and the stem portion 204 is cylindrical. The stem portion 204 extends vertically downwards from a center of the base portion 202. The stem portion 204 supports the base portion 202. The pedestal 200 includes one or more features of the pedestal 104 (e.g., the inlet 124, one or more heaters, the cooling system, one or more temperature sensors, etc.). The pedestal 200 can be used instead of the pedestal 104 in the subsystem processing system 100.

The base portion 202 includes an annular recess 206 along an outer edge 207 of the base portion 202. The annular recess 206 extends radially inwards from the outer edge 207 of the base portion 202. An inner diameter (ID) of the annular recess 206 defines an outer diameter (OD) of an upper surface 208 of the base portion 202. An OD of the annular recess 206 is equal to an OD of the base portion 202.

A highly polished (i.e., smooth) annular seal band 210 is arranged on the upper surface 208 of the base portion 202. For example, a surface roughness, which is expressed as roughness average (Ra), for the seal band 210 may be 2-8 micro-inches but with a specification limit of 16 micro-inches. An OD of the seal band 210 is equal to the OD of the upper surface 208 of the base portion 202. The OD of the seal band 210 is equal to the ID of the annular recess 206. A substrate 212 (shown in FIGS. 3-6) is arranged on the upper surface 208 of the base portion 202 during processing. The substrate 212 rests on the seal band 210 and on multiple mesas or minute projections (shown and described below in detail with reference to FIGS. 10A-10C). The mesas are distributed throughout the upper surface 208 of the base portion 202. The mesas are surrounded by the seal band 210. An OD of the substrate 212 is approximately equal to the OD of the seal band 210. The substrate 212 covers the seal band 210 (as shown in FIGS. 3-6).

FIG. 3 shows an edge ring 300 according to the present disclosure. The edge ring 300 is arranged around the base portion 202 of the pedestal 200. The edge ring 300 includes a cylindrical portion 302 and an annular portion 304. The cylindrical portion 302 extends vertically downwards from an OD of the annular portion 304 and surrounds the base portion 202 of the pedestal 200. The annular portion 304 extends radially inwards perpendicularly from a top end 303 of the cylindrical portion 302. The annular portion 304 extends horizontally over the annular recess 206 in the base portion 202 of the pedestal 200. The annular portion 304 is parallel to the annular recess 206.

A heat shield 310 is arranged below a bottom surface 220 of the base portion 202 of the pedestal 200. The heat shield 310 extends from the stem portion 204 of the pedestal 200 radially outwards and parallel to the bottom surface 220 of the base portion 202 of the pedestal 200. A bottom end 305 of the cylindrical portion 302 of the edge ring 300 rests on an upper surface 312 of the heat shield 310 at a distal end 311 of the heat shield 310. A surface-to-surface seal is created at an interface between the upper surface 312 of the heat shield 310 and a bottom surface of the cylindrical portion 302 of the edge ring 300.

In some examples, the surface-to-surface seal includes a flat-to-flat seal that is created when two flat surfaces are arranged in direct contact without joining the two surfaces using welding or using a separate seal such as an O-ring between the two surfaces. In other examples, the surface-to-surface seal includes complementary, non-planar surfaces. In other words, the abutment of the two surfaces forms the seal. In some examples, the upper surface 312 of the heat shield 310 and the bottom surface of the cylindrical portion 302 of the edge ring 300 are polished to a surface roughness (Ra) in a range from 3 to 20 micro-inches. In other examples, the surface roughness is in a range from 3 to 16 micro-inches. In other examples, the surface roughness is in a range from 3 to 8 micro-inches.

A manifold 222 is defined by the bottom surface 220 of the base portion 202 of the pedestal 200 and the upper surface 312 of the heat shield 310. A gap 320 is defined by an inner vertical surface (or inner wall) 322 of the cylindrical portion 302 of the edge ring 300 and the outer edge 207 of the base portion 202 of the pedestal 200. A gap 330 is defined by an inner (i.e., lower) horizontal surface 332 of the annular portion 304 of the edge ring 300 and the annular recess 206 in the base portion 202 of the pedestal 200. The manifold 222 is in fluid communication with the inlet 124 (shown in FIGS. 1A and 1B). For example, the inlet 124 may be connected to the manifold 222 by suitable piping within the stem portion 204. Alternatively, the inlet 124 may be directly connected to the manifold 222 instead of being connected to the bottom of the stem portion 204. The manifold 222 is in fluid communication with the gaps 320 and 330.

A distal end 307 of the annular portion 304 of the edge ring 300 (i.e., an ID of the annular portion 304 of the edge ring 300), which is opposite to the top end 303 of the cylindrical portion 302 of the edge ring 300, is spaced apart from the OD of the upper surface 208 of the base portion 202 (i.e., from a top end 211 of the annular recess 206) and from the OD of the substrate 212. A gap 308 is defined between the distal end 307 of the annular portion 304 (i.e., the ID of the annular portion 304) of the edge ring 300 and the OD of the upper surface 208 of the base portion 202 (i.e., the top end 211 of the annular recess 206) and the OD of the substrate 212. The gap 308 is in fluid communication with the gaps 320, 330 and the manifold 222.

A first portion of the inner (i.e., lower) horizontal surface 332 of the annular portion 304 of the edge ring 300 extends radially inwards from near the top end 303 of the cylindrical portion 302 and parallel to the annular recess 206. Thereafter, the remainder of the inner (i.e., lower) horizontal surface 332 of the annular portion 304 slopes upwards towards the distal end 307 of the annular portion 304 of the edge ring 300. That is, the remainder of the inner (i.e., lower) horizontal surface 332 of the annular portion 304 slopes upwards towards the ID of the annular portion 304 of the edge ring 300 at an obtuse angle.

A first portion of an outer (i.e., top) horizontal surface 334 of the annular portion 304 of the edge ring 300 extends radially inwards from the top end 303 of the cylindrical portion 302 and parallel to the annular recess 206. Thereafter, the remainder of the outer horizontal surface 334 of the annular portion 304 slopes downwards towards the distal end 307 of the annular portion 304 of the edge ring 300. That is, the remainder of the outer horizontal surface 334 of the annular portion 304 slopes towards the ID of the annular portion 304 of the edge ring 300 at an obtuse angle.

Accordingly, the inner (i.e., lower) horizontal surface 332 and the outer (i.e., top) horizontal surface 334 of the annular portion 304 extend radially inwards from the top end 303 of the cylindrical portion 302 and parallel to the annular recess 206 for a distance. Thereafter, the remainder portions of the inner (i.e., lower) horizontal surface 332 and the outer (i.e., top) horizontal surface 334 of the annular portion 304 taper towards and converge at the distal end 307 (i.e., at the ID) of the annular portion 304 at an obtuse angle. The distal end 307 (i.e., the ID) of the annular portion 304 is rounded.

The outer (i.e., top) horizontal surface 334 of the annular portion 304 of the edge ring 300 is not aligned with (i.e., is not in the same plane as) a top surface 213 of the substrate 212. Rather, the outer (i.e., top) horizontal surface 334 of the annular portion 304 of the edge ring 300 is parallel to the top surface 213 of the substrate 212 and lies in a plane that is slightly higher than a plane in which lies the top surface 213 of the substrate 212.

During processing, the pedestal 200, with the substrate 212 arranged on the upper surface 208 of the base portion 202 of the pedestal 200, is moved closer to a showerhead (not shown). The showerhead is fixed above the substrate 212 and the pedestal 200 in a processing chamber (e.g., see the showerhead 114 in the processing chamber 102 shown in FIGS. 1A and 1B). A small gap exists between the showerhead and the outer (i.e., top) horizontal surface 334 of the annular portion 304 of the edge ring 300. For example, the gap between the edge ring 300 and the showerhead may be about 0.050″, and the gap between the top surface 213 of the substrate 212 and the faceplate of the showerhead may be about 0.150″. The showerhead deposits material (e.g., using ALD) on the top surface (i.e., the front side) 213 of the substrate 212.

During deposition, a purge gas flows from the inlet 124 (shown in FIGS. 1A and 1B) through the manifold 222 and the gaps 320, 330, 308. The purge gas flows over the outer (i.e., top) horizontal surface 334 of the annular portion 304 of the edge ring 300. The purge gas exits by flowing through a gap between the showerhead and the outer (i.e., top) horizontal surface 334 of the annular portion 304 of the edge ring 300. The flow of the purge gas is shown by arrows 336-1, 336-2, 336-3, 336-4, and 336-5 (collectively the arrows 336). The flow of the purge gas is controlled (e.g., by the system controller 160 shown in FIGS. 1A and 1B). The flow of the purge gas prevents deposition on a bottom surface (i.e., a backside) 214 of the substrate 212.

Throughout the present disclosure, for the purposes of preventing backside deposition on substrates, the backside 214 of the substrate 212 is defined as an area of the substrate 212 beginning at a bottom edge of the bevel of the substrate 212 and extending to the center of the backside 214 of the substrate 212. The process gases delivered to the top surface (i.e., the front side) 213 of the substrate 212 by the showerhead during deposition flow in the direction indicated by arrows 338-1, 338-2 (collectively the arrows 338). During deposition, the process gases flowing in the direction shown by the arrows 338 help push the purge gas to flow in the direction shown by the arrows 336. The flow of the purge gas during deposition does not affect the deposition on the top surface (i.e., the front side) 213 of the substrate 212.

To further prevent deposition from occurring on the backside 214 of the substrate 212, the substrate 212 is clamped to the upper surface 208 of the pedestal 200 using electrostatic clamping as described with reference to FIG. 1A. Alternatively, the substrate 212 is clamped to the upper surface 208 of the pedestal 200 using vacuum clamping shown and described below in detail with reference to FIGS. 9A-9B. In either approach, the amount of clamping force exerted on the substrate 212 is controlled by the system controller 160 shown in FIGS. 1A and 1B.

To further enhance the clamping force on the substrate 212, the upper surface 208 of the pedestal 200 may be machined to have either a slight dish or dome like shape. Accordingly, the OD of the upper surface 208 of the pedestal 200 may be slightly higher (if the upper surface 208 is dish shaped) or lower (if the upper surface 208 is dome shaped) than the center of the upper surface 208 of the pedestal 200. The OD of the substrate 212 rests on the seal band 210. The curved shaping of the upper surface 208 of the pedestal 200 enhances the clamping force with which the substrate 212 is clamped to the seal band 210 on the upper surface 208 of the pedestal 200. The enhanced clamping force further prevents deposition from occurring on the backside 214 of the substrate 212. The curved shaping of the upper surface 208 of the pedestal 200 is shown and described below in further detail with reference to FIGS. 10A-10C.

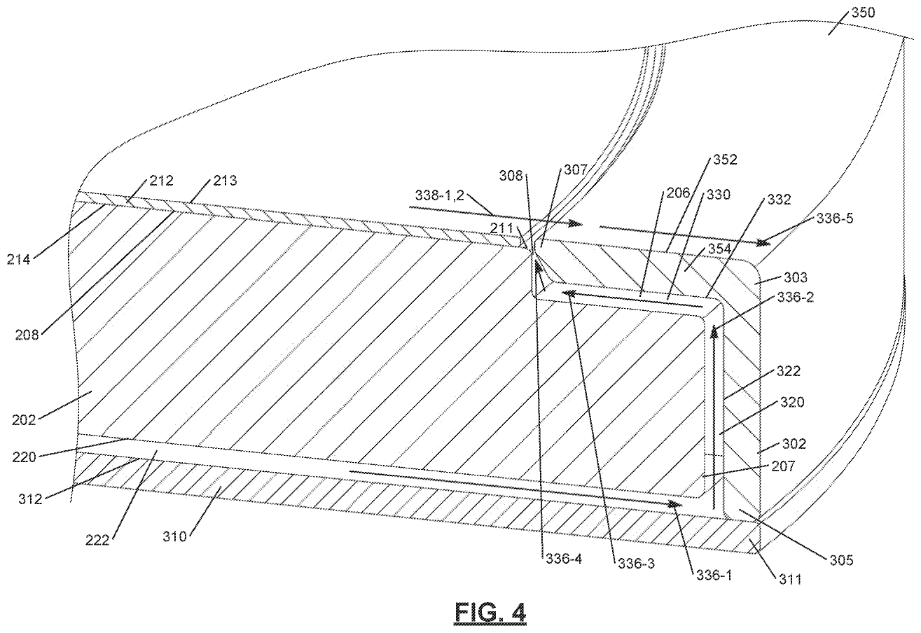

FIG. 4 shows an edge ring 350 according to the present disclosure. The edge ring 350 differs from the edge ring 300 in only one respect. An outer (i.e., top) horizontal surface 352 of an annular portion 354 of the edge ring 350 extends radially inwards from the top end 303 of the cylindrical portion 302 and parallel to the annular recess 206 but does not slope downwards towards the distal end 307 of the annular portion 354 of the edge ring 350 (i.e., the ID of the annular portion 354 of the edge ring 350) at an obtuse angle. Instead, the outer (i.e., top) horizontal surface 352 of the annular portion 354 of the edge ring 350 is flat and extends radially inwards along a straight line from the top end 303 of the cylindrical portion 302 and parallel to the annular recess 206 all the way to the distal end 307 of the annular portion 354 of the edge ring 350 (i.e., the ID of the annular portion 354 of the edge ring 350). The outer (i.e., top) horizontal surface 352 of the annular portion 354 of the edge ring 350 is aligned with (i.e., lies in the same plane as) the top surface 213 of the substrate 212. Accordingly, the outer (i.e., top) horizontal surface 352 of the annular portion 354 of the edge ring 350 is not only parallel to the top surface 213 of the substrate 212 but is also level with the top surface 213 of the substrate 212.

The flatness of the outer (i.e., top) horizontal surface 352 of the annular portion 354 of the edge ring 350 and the alignment of the outer (i.e., top) horizontal surface 352 of the annular portion 354 of the edge ring 350 with the top surface 213 of the substrate 212 help the purge gas to flow out of the gap between the showerhead and the edge ring 350 faster than in the edge ring 300, which further prevents the deposition on the backside 214 of the substrate 212 and does not affect the deposition on the top surface (i.e., the front side) 213 of the substrate 212. All other description of the edge ring 300 applies to the edge ring 350 and is therefore not repeated for brevity.

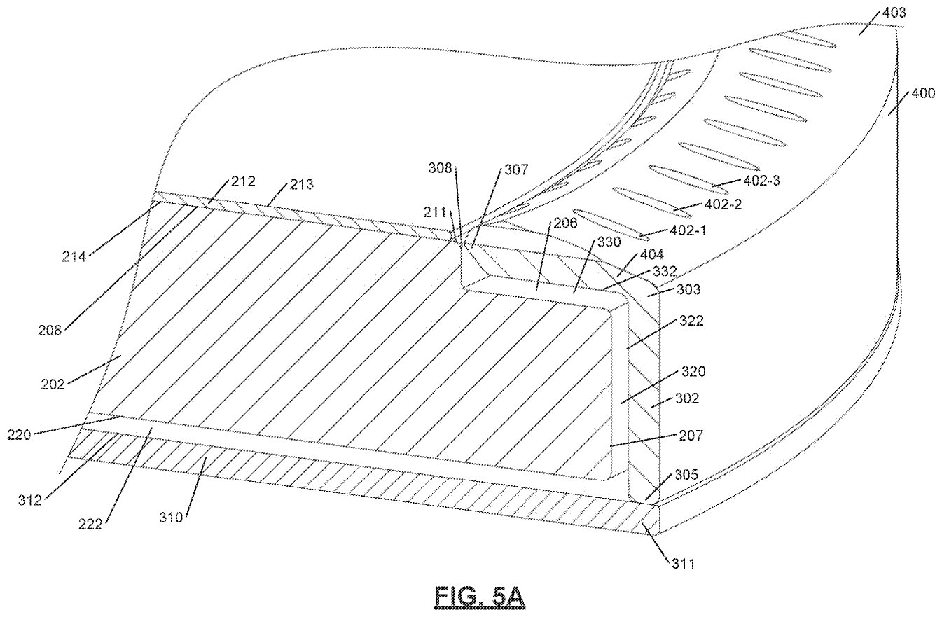

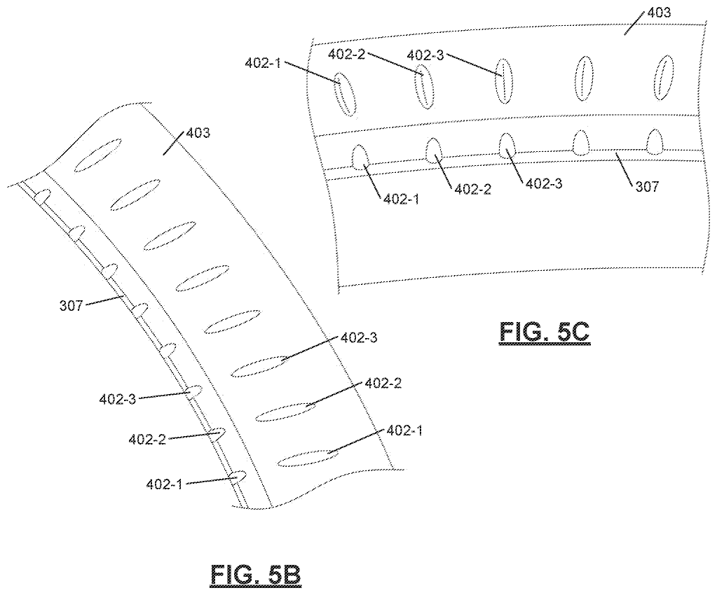

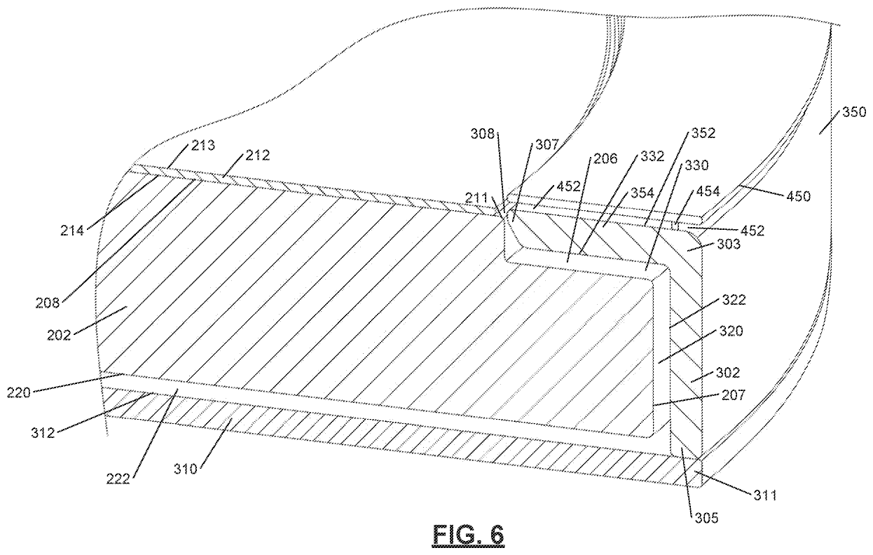

FIGS. 5A-5C shows an edge ring 400 according to the present disclosure. In FIG. 5A, the edge ring 400 differs from the edge ring 300 in two respects. First, the edge ring 400 includes a plurality of radially extending holes 402-1, 402-2, 403-3, and so on (collectively holes 402) in an annular portion 404 of the edge ring 400; and second, an outer (i.e., top) surface 403 of the annular portion 404 of the edge ring 400 extends radially inwards from the top end 303 of the cylindrical portion 302 sloping upwards for a distance and then slopes downwards towards the distal end 307 of the annular portion 404 of the edge ring 400 (i.e., towards the ID of the annular portion 404 of the edge ring 400).

Accordingly, the outer (i.e., top) surface 403 of the annular portion 404 of the edge ring 400 is not parallel to the annular recess 206. Instead, the outer (i.e., top) surface 403 of the annular portion 404 of the edge ring 400 includes two sloping portions that respectively slope downwards towards the ID and OD of the annular portion 404 of the edge ring 400 (i.e., towards both the distal end 307 of the annular portion 404 and the top end 303 of the cylindrical portion 302). Accordingly, the outer (i.e., top) surface 403 of the annular portion 404 of the edge ring 400 is not only not aligned with (i.e., is not in the same plane as) the top surface 213 of the substrate 212 but is also not parallel to the top surface 213 of the substrate 212.

The dual sloping feature of the outer (i.e., top) surface 403 of the annular portion 404 of the edge ring 400 and the holes 402 help the purge gas to flow out of the gap between the showerhead and the edge ring 400 faster than in the edge ring 300, which further prevents the deposition on the backside 214 of the substrate 212 and does not affect the deposition on the top surface (i.e., the front side) 213 of the substrate 212. All other description of the edge ring 300 applies to the edge ring 400 and is therefore not repeated for brevity.

Additional views of the holes 402 are shown in FIGS. 5B and 5C. In FIGS. 5B and 5C, each of the holes 402 begins at the distal end 307 of the annular portion 404 of the edge ring 400 (i.e., at the ID of the annular portion 404 of the edge ring 400) and extends radially outwards towards the OD of the annular portion 404 of the edge ring 400 (i.e., towards the top end 303 of the cylindrical portion 302 of the edge ring 400). Accordingly, the purge gas not only flows and exits by flowing over the outer (i.e., top) surface 403 of the annular portion 404 of the edge ring 400, but additionally flows out through the holes 402. The additional flow of purge gas through the holes 402 further prevents the deposition on the backside 214 of the substrate 212 and does not affect the deposition on the top surface (i.e., the front side) 213 of the substrate 212. The volume and flow rate of the purge gas can be controlled (e.g., by the system controller 160 shown in FIGS. 1A and 1B) based on the dimensions and density of the holes 402.

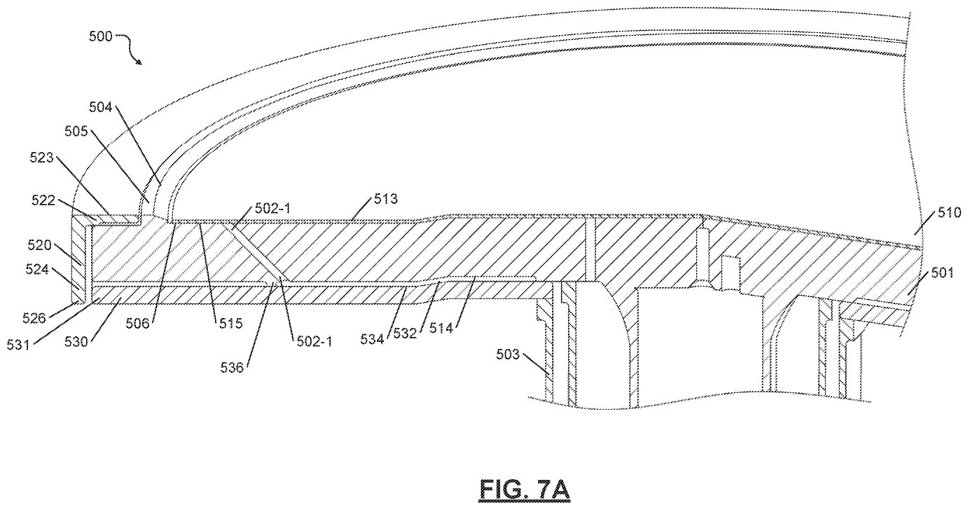

FIG. 6 shows the edge ring 350 and an additional second ring 450 arranged above and parallel to the annular portion 354 of the edge ring 350. The second ring 450 is a flat and thin annular (i.e., disc shaped) structure arranged above and parallel to the outer (i.e., top) horizontal surface 352 of the annular portion 354 of the edge ring 350. A width of the second ring 450 (i.e., a distance between an ID and OD of the second ring 450) is about the same as a width of the annular portion 354 of the edge ring 350 (i.e., a distance between the ID of the annular portion 354 and the OD of the cylindrical portion 302 of the edge ring 350). A thickness of the second ring 450 may be about the same as a thickness of the substrate 212. The second ring 450 is arranged along a plane parallel to and slightly above the plane of the substrate 212. The second ring 450 is also parallel to the annular recess 206.

The second ring 450 is connected to (i.e., mounted on) the outer (i.e., top) horizontal surface 352 of the annular portion 354 of the edge ring 350 using posts 454 arranged at three or more locations on the outer (i.e., top) horizontal surface 352 of the annular portion 354. The posts 454 may be located anywhere on the outer (i.e., top) horizontal surface 352 of the annular portion 354 of the edge ring 350. The posts 454 may be preferably arranged closer to the OD of the annular portion 354 of the edge ring 350 so as to not obstruct an exhaust path of the purge gas. The purge gas exits through a gap 452 between a bottom of the second ring 450 and the outer (i.e., top) horizontal surface 352 of the annular portion 354 of the edge ring 350.

During processing, the showerhead may be proximate to or may rest on top of the second ring 450. The flatness of the second ring 450 and the outer (i.e., top) horizontal surface 352 of the annular portion 354 of the edge ring 350 helps the purge gas to flow out of the gap 452 between the second ring 450 and the edge ring 350 faster than in the edge ring 300, which further prevents the deposition on the backside 214 of the substrate 212 and does not affect the deposition on the top surface (i.e., the front side) 213 of the substrate 212. All other description of the edge ring 300 applies to the edge ring 350 and is therefore not repeated for brevity.

FIGS. 7A-7C show a pedestal 500 that supplies a purge gas through a plurality of holes 502-1, 502-2, 502-3, and so on (collectively holes 502) in the pedestal 500 to prevent backside deposition on a substrate 510 according to the present disclosure. The pedestal 500 includes a base portion 501 and a stem portion 503. The base portion 501 is disc shaped. The stem portion 503 is cylindrical. The stem portion 503 extends vertically downwards from a center of the base portion 501. The stem portion 503 supports the base portion 501. The pedestal 500 includes one or more features of the pedestal 104 (e.g., the inlet 124, one or more heaters, the cooling system, one or more temperature sensors, etc.). The pedestal 500 can be used instead of the pedestal 104 in the subsystem processing system 100. FIGS. 7A and 7C show a substrate 510 arranged on the pedestal 500. FIG. 7B shows the pedestal 500 without the substrate 510 to illustrate additional features of the pedestal 500.

The base portion 501 of the pedestal 500 includes an annular ridge 504 on a top surface 506 of the base portion 501. The annular ridge 504 is located closer to an OD of the base portion 501 of the pedestal 500. The annular ridge 504 surrounds the substrate 510 arranged on the top surface 506 of the base portion 501 of the pedestal 500. An ID of the annular ridge 504 is about the same as (i.e., greater than or equal to) an OD of the substrate 510. An OD of the annular ridge 504 is less than the OD of the base portion 501 of the pedestal 500.

The annular ridge 504 ascends vertically from the top surface 506 of the base portion 501 at the ID of the annular ridge 504, extends outwards (i.e., away from the center of the base portion 501) at an angle relative to a vertical axis of the stem portion 503, then extends radially outwards parallel to the top surface 506 of the base portion 501, and then descends vertically to the top surface 506 of the base portion 501 at the OD of the annular ridge 504.

The annular ridge 504 may be machined as an integral portion of the top surface 506 of the base portion 501. Alternatively, the annular ridge 504 may be separate from the pedestal 500, may be in the form a ring having the geometry described above, and may be attached to the top surface 506 of the base portion 501.

The holes 502 are arranged along a first circle on the top surface 506 of the base portion 501. The first circle has a smaller diameter than the ID of the annular ridge 504. Accordingly, the annular ridge 504 surrounds the holes 502. The holes 502 extend downwards through the base portion 501 of the pedestal 500 and through a bottom surface 514 of the base portion 501. The holes 502 descend inwardly (i.e., towards the center of the pedestal 500) from the top surface 506 to the bottom surface 514 of the base portion 501 at an angle relative to a vertical axis of the stem portion 503 of the pedestal 500. For example, the angle may be 45 degrees. For example, the angle may be between 30 and 60 degrees. The holes 502 in the bottom surface 514 of the base portion 501 lie along a second circle having a smaller diameter than the first circle.

A highly polished (i.e., smooth) annular seal band 512 is arranged on the top surface 506 of the base portion 501. An OD of the seal band 512 is less than the diameter of the first circle along which the holes 502 are arranged on the top surface 506 of the base portion 501. Accordingly, the holes 502 surround the seal band 512. An OD the substrate 510 is greater than the OD of the seal band 512 and the diameter of the first circle along which the holes 502 lie on the top surface 506 of the base portion 501. A substantial portion of the substrate 510 radially extends beyond the seal band 512 and the holes 502 up to the ID of the annular ridge 504.

An annular L-shaped ring 520 surrounds the OD of the annular ridge 504 and the OD of the base portion 501 of the pedestal. The ring 520 acts as a heat shield. The horizontal portion 522 of the ring 520 rests on the top surface 506 of the base portion 501 between the OD of the annular ridge 504 and the OD of the base portion 501. A top surface 523 of the horizontal portion 522 of the ring 520 is level with (i.e., is in the same plane as) a top surface 505 of the annular ridge 504.

A heat shield 530 is arranged below the bottom surface 514 of the base portion 501 of the pedestal 500. The heat shield 530 extends from the stem portion 503 of the pedestal 500 radially outwards and parallel to the bottom surface 514 of the base portion 501 of the pedestal 500. A distal end 531 of the heat shield 530 extends up to the OD of the base portion 501 of the pedestal 500 and aligns with a bottom end 526 of a vertical portion 524 of the ring 520.

An annular protrusion 536 on the bottom surface 514 of the base portion 501 is connected to a top surface 534 of the heat shield 530. The annular protrusion 536 surrounds the holes 502 in the bottom surface 514 of the base portion 501. The annular protrusion 536 is adjacent to the holes 502 in the bottom surface 514 of the base portion 501. The annular protrusion 536 has a greater diameter than the second circle along which the holes 502 lie in the bottom surface 514 of the base portion 501. The diameter of the annular protrusion 536 is less than the diameter of the first circle along which the holes 502 lie in the top surface 506 of the base portion 501.

A manifold 532 is defined by the bottom surface 514 of the base portion 501 of the pedestal 500, the top surface 534 of the heat shield 530, and the annular protrusion 536. The manifold 532 is in fluid communication with the holes 502 and the inlet 124 (shown in FIGS. 1A and 1B). For example, the inlet 124 may be connected to the manifold 532 by suitable piping within the stem portion 503. Alternatively, the inlet 124 may be directly connected to the manifold 532 instead of being connected to the bottom of the stem portion 503.

During processing, the pedestal 500, with the substrate 510 arranged on the top surface 506 of the base portion 501 of the pedestal 500, is moved closer to a showerhead 540, which is fixed above the substrate 510 and the pedestal 500 in a processing chamber (e.g., the processing chamber 102 shown in FIGS. 1A and 1B). A small gap exists between the showerhead 540 and the top surface 505 of the annular ridge 504. For example, the gap between top surface 505 of the annular ridge 504 and the showerhead 540 may be about 0.050″, and the gap between the top surface 513 of the substrate 510 and the faceplate of the showerhead 540 may be about 0.150″. The showerhead deposits material (e.g., using ALD) on a top surface (i.e., the front side) 513 of the substrate 510.

During deposition, a purge gas flows from the inlet 124 (shown in FIGS. 1A and 1B) through the manifold 532 and the holes 502 onto a portion of a bottom surface (i.e., a backside) 515 of the substrate 510 that is between the OD of the substrate 510 and the first circle along which lie the holes 502 in the top surface 506 of the base portion 501. The purge gas exits by flowing over the annular ridge 504 (i.e., through a gap between the showerhead 540 and the top surface 534 of the annular ridge 504) and over the top surface 523 of the horizontal portion 522 of the ring 520. The process gases from the showerhead 540 also exit by flowing over the annular ridge 504 (i.e., through a gap between the showerhead 540 and the top surface 534 of the annular ridge 504) and over the top surface 523 of the horizontal portion 522 of the ring 520. The flow of the purge gas through the holes 502 onto the backside 515 of the substrate 510 towards the OD of the substrate 510 prevents deposition on the bottom surface (i.e., a backside) 515 of the substrate 510. Again, for the purposes of preventing backside deposition on substrates, the backside 515 of the substrate 510 is defined as an area of the substrate 510 beginning at a bottom edge of the bevel of the substrate 510 and extending to the center of the backside 515 of the substrate 510.

The volume and flow rate of the purge gas can be controlled (e.g., by the system controller 160 shown in FIGS. 1A and 1B) based on the dimensions and density of the holes 502. The flow of the purge gas through the holes 502 during deposition does not affect the deposition of material from the showerhead 540 on the top surface (i.e., the front side) 513 of the substrate 510. To further prevent deposition from occurring on the backside 515 of the substrate 510, the substrate 510 is clamped to the top surface 506 of the pedestal 500 using either electrostatic clamping or vacuum clamping as described with reference to FIGS. 1A and 1B.

FIG. 8 shows a method 600 for preventing backside deposition on substrates according to the present disclosure. A controller of a substrate processing system (e.g., element 160 shown in FIGS. 1A and 1B) may perform some of the steps of the method 600. In the method 600, at 602, a substrate is placed on a pedestal (e.g., element 200 shown in FIG. 2 or element 500 shown in FIG. 7A). At 604, the pedestal is moved closer to a showerhead. At 606, the method 600 determines whether to being the processing (e.g., deposition) of the substrate.

At 608, the method 600 begins processing the substrate by depositing material (e.g., using ALD) on the front side of the substrate from the showerhead. At 610, while the processing (e.g., deposition) is ongoing, the method 600 supplies a purge gas around the edge of the substrate (e.g., using the pedestal 200 of FIG. 2 and any of the edge rings shown in FIGS. 3-6). Alternatively, the method 600 supplies a purge gas from under the substrate towards the edge of the substrate (e.g., using the pedestal shown in FIGS. 7A-7C). The purge gas prevents deposition on the backside of the substrate (i.e., throughout the area of the substrate from a bottom edge of the bevel to the center of the bottom surface of the substrate).

FIGS. 9A and 9B show an example of a pedestal 700 employing vacuum clamping according to the present disclosure. Any of the edge rings shown in FIGS. 3-6 can be used with the pedestal 700 to prevent backside deposition as described above. In FIG. 9A, the pedestal 700 includes a base portion 702 and a stem portion 704. In some examples, the base portion 702 is disc shaped, and the stem portion 704 is cylindrical. The stem portion 704 extends vertically downwards from a center of the base portion 702. The stem portion 704 supports the base portion 702. The stem portion 704 provides vacuum clamping and purge gas flow as described below in detail with reference to FIG. 9B. The pedestal 700 includes one or more features of the pedestal 103 of FIG. 1B (e.g., the inlet 124, one or more heaters, the cooling system, one or more temperature sensors, etc.). The pedestal 700 can be used instead of the pedestal 103 in the subsystem processing system 101 in FIG. 1B.

The base portion 702 includes an annular recess 706 along an outer edge 707 of the base portion 702. The annular recess 706 extends radially inwards from the outer edge 707 of the base portion 702. An inner diameter (ID) of the annular recess 706 defines an outer diameter (OD) of an upper surface 708 of the base portion 702. An OD of the annular recess 706 is equal to an OD of the base portion 702.

A highly polished (i.e., smooth) annular seal band 710 (see FIG. 9A) is arranged on the upper surface 708 of the base portion 702. The seal band 710 is similar to the seal band 210 shown in FIG. 2. For example, a surface roughness, which is expressed as roughness average (Ra), for the seal band 710 may be 2-8 micro-inches but with a specification limit of 16 micro-inches. An OD of the seal band 710 is equal to the OD of the upper surface 708 of the base portion 702. The OD of the seal band 710 is equal to the ID of the annular recess 706.

A substrate 212 (shown in FIGS. 3-6) is arranged on the upper surface 708 of the base portion 702 during processing. The substrate 212 rests on the seal band 710 and on multiple mesas or minute projections (shown and described below in detail with reference to FIGS. 10A-10C). The mesas are distributed throughout the upper surface 708 of the base portion 702. The mesas are surrounded by the seal band 710. An OD of the substrate 212 is approximately equal to the OD of the seal band 710. The substrate 212 covers the seal band 710 (as shown with the seal band 210 in FIGS. 3-6).

For example only, the edge ring 300 is arranged around the base portion 702 of the pedestal 700. The edge ring 300 is already described above in detail with reference to FIG. 3. The description of the edge ring 300 is therefore omitted for brevity. Alternatively, any of the edge rings shown in FIGS. 4-6 can be used with the pedestal 700 instead of the edge ring 300. The vacuum clamping is now described in detail.

FIG. 9B shows the stem portion 704 in further detail. The stem portion 704 provides vacuum clamping and purge gas flow as follows. The following description includes various instances of forming a surface-to-surface seal. The method of forming a surface-to-surface seal is already described above in detail with reference to FIG. 3 and is therefore omitted for brevity.

The stem portion 704 includes a support structure 750 of the pedestal 700. The support structure 750 includes a first cylindrical portion 752 and a second cylindrical portion 744. An upper and radially outer end of the first cylindrical portion 752 includes a flange 742. The flange 742 extends radially outwards from the upper and radially outer end of the first cylindrical portion 752. An upper and radially inner end of the first cylindrical portion 752 includes a slot 740. The second cylindrical portion 744 extends vertically upwards from an upper and radially outer end of the flange 742. The second cylindrical portion 744 has a greater diameter than the first cylindrical portion 752.

The bottom of the stem portion 704 of the pedestal 710 is connected to the support structure 750 using one or more clamps. In some examples, the one or more clamps include clamping rings with an annular or split annular shape. A first clamp 850 is connected by one or more fasteners 852-1, 852-2, and so on (collectively the fasteners 852) through a second clamp 854 to an inner surface of the support structure 750. As used herein, the term clamp refers to an annular or arcuate portion that is fastened to another component to hold one or more components together.

The first clamp 850 is spaced from a side wall 720 (described below in detail) of the stem portion 704. An inner surface of the first clamp 850 and an outer surface of the side wall 720 of the stem portion 704 define a cavity 853. The second clamp 854 includes a plurality of through holes 855-1, 855-2, and so on (collectively the through holes 855). The cavity 853 and the through holes 855 are in fluid communication with each other. As described below in detail, the cavity 853 and the through holes 855 provide a passage for gases suctioned by the vacuum pump 158 from under a substrate mounted on the upper surface 708 of the pedestal 700.

A third clamp 770 is attached to a bottom facing surface of the flange 742 of the first cylindrical portion 752 of the support structure 750. In some examples, the third clamp 770 has an “L”-shaped cross-section and includes an upwardly projecting portion 774 and a radially inwardly projecting portion 772. The third clamp 770 surrounds an upper portion of the support structure 750.

A first end of the radially inwardly projecting portion 772 extends radially inwards from a lower end of the upwardly projecting portion 774. A second end of the radially inwardly projecting portion 772 forms a surface-to-surface seal with an outer wall 775 of the first cylindrical portion 752 of the support structure 750. A lower end of the flange 742 rests on and forms a surface-to-surface seal with an upper surface 776 of the radially inwardly projecting portion 772.

The upwardly projecting portion 774 extends vertically upwards from a radially outer end (i.e., the first end) of the radially inwardly projecting portion 772. An inner surface of the upwardly projecting portion 774 is spaced from an outer surface of the second cylindrical portion 744 of the support structure 750. The inner surface of the upwardly projecting portion 774 and the outer surface of the second cylindrical portion 744 define a cavity 780.

An upper end of the upwardly projecting portion 774 includes a flange 779. The flange 779 extends radially outwards from the upper end of the upwardly projecting portion 774. A first vertical portion 778 extends vertically upwards from a radially outer end of the flange 776. A second vertical portion 782 extends vertically upwards from near a radially inner end of the flange 776. The first and second vertical portions 778 and 782 are spaced apart from each other and define a cavity 784. The first and second vertical portions 778 are of approximately equal height. The flange 779 and the first and second vertical portions 778 and 782 form a U-shaped (or a fork-shaped) structure 781.

A radially inner portion 790 of the upper end of the upwardly projecting portion 774 projects radially inwards and forms a surface-to-surface seal with the outer surface of the second cylindrical portion 744 of the support structure 750. The radially inner portion 790 is located radially opposite to the flange 779. Specifically, the radially inner portion 790 also extends radially inwards from a lower and radially inner portion of the second vertical portion 782.

A bore 788 extends at an angle from a radially inner and upper end of the upwardly projecting portion 774 to an upper surface of the flange 779. The bore 788 is in fluid communication with the cavity 784 defined by the first and second vertical portions 778 and 782. The bore 788 is also in fluid communication with the cavity 780 defined by the inner surface of the upwardly projecting portion 774 and the outer surface of the second cylindrical portion 744. The bore 788 and the cavities 784, 780 provide a passage for the purge gas as described below.

The stem portion 704 includes the side wall 720. The side wall 720 extends vertically downwards from a center region 715 of a bottom surface 716 of the base portion 702 as shown in FIG. 9A. A flange 726 is located at a lower end of the side wall 720. The flange 726 extends radially outwardly from the side wall 720. A lower end of the flange 726 is arranged in the slot 740 in the support structure 750. An O-ring 748 arranged in the slot 740 under the lower end of the flange 726 to form a seal. The side wall 720 defines an inner cavity 724 of the stem portion 704. Connections (not shown) to electrical components (e.g., heaters, heat sensors, etc.) located in the base portion 702 are provided through the inner cavity 724.

A collar 730 is spaced from and surrounds the side wall 720 of the stem portion 704 of the pedestal 700. The collar 730 and the side wall 720 define an annular volume 725 between an inner surface of the collar 730 and an outer surface of the side wall 720 of the stem portion 704 of the pedestal 700. The collar 730 includes flanges 734 and 736 extending radially outwardly from the lower and upper ends thereof, respectively. A radially outer surface of the flange 734 forms a surface-to-surface seal with a radially inner surface of the second vertical portion 782 of the U-shaped structure 781. An upper surface of the flange 736 forms a surface-to-surface seal with the bottom surface 716 of the base portion 702. The annular volume 725 is fluid communication with the cavity 853 between the first clamp 850 and the side wall 720 and with the through holes 855 in the second clamp 854.

The upper surface 708 of the base portion 702 of the pedestal includes a plurality of through holes 712-1, 712-2, 712-3, and so on (collectively the through holes 712). The through holes 712 extend vertically downwards from the upper surface 708 through the bottom surface 716 of the base portion 702. The through holes 712 are arranged along a circle. The diameter of the circle is greater than an OD of the side wall 720 of the stem portion 704. The diameter of the circle is less than an ID of the collar 730. The through holes 712 are in fluid communication with the annular volume 725 between the side wall 720 and the collar 730. The through holes 712 are also in fluid communication with the cavity 853 between the first clamp 850 and the side wall 720 and with the through holes 855 in the second clamp 854. As explained below, the through holes 712, the annular volume 725, the cavity 853, and the through holes 855 provide a passage for gases to be suctioned out and to form vacuum under a substrate placed on the base portion 702 of the pedestal 700.

The first cylindrical portion 752 of the support structure 750 includes a bore 800. The bore 800 is in fluid communication with the annular volume 725 between the side wall 720 and the collar 730. The bore 800 is in fluid communication with the valve 162 (see FIG. 1B). During processing, a substrate (e.g., the substrate 212 shown in FIG. 3) is placed on the upper surface 708 of the pedestal 700. The system controller 160 activates the valve 162. The vacuum pump 158 creates vacuum under the substrate 212 by removing gases from under the substrate 212 via the through holes 712, the annular volume 725, the cavity 853, the through holes 855, the bore 800, and the valve 162. For example, the flow of gases is indicated by downward pointing arrows 802-1, 802-2, and 802-3 (collectively the arrows 802). Due to the vacuum, the substrate 212 is clamped to the upper surface 708 of the pedestal 700.

A heat shield 810 shown in FIG. 9A is similar to the heat shield 310 shown in FIGS. 3-6. The heat shield 810 is arranged a predetermined distance below the bottom surface 716 of the base portion 702 of the pedestal 700. The heat shield 810 is annular. The heat shield 810 includes a central opening wide enough to receive the collar 730 and the stem portion 704 of the pedestal 700. The heat shield 810 extends from an upper end of the stem portion 704 of the pedestal 700 radially outwards and parallel to the bottom surface 716 of the base portion 702 of the pedestal 700. The bottom end 305 of the cylindrical portion 302 of the edge ring 300 rests on an upper surface 812 of the heat shield 810 at a distal end 811 of the heat shield 810. A surface-to-surface seal is created (as explained above in detail with reference to FIG. 3) at an interface between the upper surface 812 of the heat shield 810 and a bottom surface of the cylindrical portion 302 of the edge ring 300.

A manifold 822 is defined by the bottom surface 716 of the base portion 702 of the pedestal 700 and the upper surface 812 of the heat shield 810. A gap 820 is defined by an inner vertical surface (or inner wall) 322 of the cylindrical portion 302 of the edge ring 300 and the outer edge 707 of the base portion 702 of the pedestal 700. A gap 830 is defined by an inner (i.e., lower) horizontal surface 332 of the annular portion 304 of the edge ring 300 and the annular recess 706 in the base portion 702 of the pedestal 700. The gaps 820 and 830 are in fluid communication with the manifold 822. Additional details of the edge ring 300 are described above with reference to FIG. 3 and are therefore omitted for brevity.

The heat shield 810 includes a vertical portion 880. The vertical portion 880 extends vertically downwards from a center region of the heat shield 810. The vertical portion 880 is spaced from and surrounds the collar 730. A distal end of the vertical portion 880 includes a flange 882. The flange 882 extends radially outwards from the distal end of the vertical portion 880. The radially outer surface of the flange 882 forms a surface-to-surface seal with a radially inner surface of the first vertical portion 778 of the U-shaped structure 781. An inner surface of the vertical portion 880 and an outer surface of the collar 730 define a second annular volume 884. The second annular volume 884 is separate from the annular volume 725. The second annular volume 884 is not fluidly connected to the annular volume 725. The second annular volume is in fluid communication with the cavity 784, the bore 788, and the cavity 780. The manifold 822 is in fluid communication with the second annular volume 884.

The first cylindrical portion 752 of the support structure 750 includes a second bore 886. The bore 886 extends vertically upwards through the first cylindrical portion 752 and then radially through the flange 742. The bore 886 is in fluid communication with the cavity 780, the bore 788, the cavity 784, the second annular volume 884, and the manifold 722. The bore 886 is in fluid communication with the inlet 124 and valve 164 (see FIG. 1B).

During processing, a substrate (e.g., the substrate 212 shown in FIG. 3) is arranged on the upper surface 708 of the pedestal 700. The system controller 160 activates the valve 164. The purge gas flows though the valve 164, the inlet 124, the bore 886, the cavity 780, the bore 788, the cavity 784, the second annular volume 884, the manifold 722, and the gaps 820 and 830 between the edge ring 300 and the base portion 702 of the pedestal 700. For example, the flow of the purge gas is indicated by upward pointing arrows 890-1, 890-2, and 890-3 (collectively the arrows 890). The purge gas prevents deposition on the backside of the substrate 212.

As described above, the design of the stem portion 704 of the pedestal 700 provides separate (i.e., independent) passages for the vacuum clamping and the purge gas. The passages are not in fluid communication with each other. Gases flow though the passages in opposite directions as described above. The passages for the vacuum clamping and the purge gas provided by the stem portion 704 can also be used with the pedestal 500 shown in FIGS. 7A-7C.

FIGS. 10A-10C show an example of the mesas provided on the upper portion 708 of the pedestal 700. FIG. 10A shows a plan view of the base portion 702 of the pedestal 700. FIG. 10B shows a cross-section of the base portion 702. FIG. 10C shows the mesas in detail. To focus on the mesas, all other features of the base portion 702 (e.g., the through holes 712) are omitted. The mesas can also be similarly employed in the pedestals 200 and 500 shown and described above with reference to FIGS. 2-7C.

FIG. 10A shows mesas 900-1, 900-2, and so on (collectively the mesas 900). The mesas 900 are minute projections (see FIG. 10C). For example only, the mesas 900 can be cylindrical in shape. The mesas 900 can have any other shape. The mesas 900 are surrounded by the seal band 710 disposed along the OD of the upper surface 708 of the base portion 702 of the pedestal 700. The mesas 900 populate the upper surface 708 of the base portion 702 of the pedestal 700. The mesas 900 are distributed from the center of upper surface 708 of the base portion 702 to the ID of the seal band 710. Alternatively, the mesas 900 are distributed from the center of upper surface 708 of the base portion 702 to the OD of the upper surface 708 of the base portion 702 of the pedestal 700.

The mesas 900 can be machined to have varying heights. For example, the mesas 900 can be machined to provide a convex or a concave shape to the upper portion 708 of the pedestal 700. For example only, for a pedestal designed to process a 13″ substrate, the mesas 900 can be machined to provide a curvature of a sphere having a diameter of 50 feet. FIG. 10B shows an example of a concave shape provided by the mesas 900 to the upper portion 708 of the pedestal 700. The example shown is not to scale. The example shown in exaggerated for illustrative purposes. The example shows that a peripheral region 904 of the upper portion 708 of the pedestal 700 lies in a higher plane than a center region 902 of the upper portion 708 of the pedestal 700. In the example shown, the height of the mesas 900 decreases from the peripheral region 904 of the upper portion 708 of the pedestal 700 to the center region 902 of the upper portion 708 of the pedestal 700.

Conversely, the mesas 900 can provide a convex shape to the upper portion 708 of the pedestal 700. In this example, the peripheral region 904 of the upper portion 708 of the pedestal 700 will lie in a lower plane than the center region 902 of the upper portion 708 of the pedestal 700. In this example, the height of the mesas 900 will increase from the peripheral region 904 of the upper portion 708 of the pedestal 700 to the center region 902 of the upper portion 708 of the pedestal 700.

In another example, the mesas 900 can also be machined to provide a flat surface on which a substrate can be placed during processing. In this example, all of the mesas 900 will be of equal (uniform) height. Alternatively, the mesas 900 can be machined to provide a tilted surface (from one radial edge to an opposite radial edge of the upper surface 708 of the base portion 702) on which a substrate can be placed during processing. In this example, the height of the mesas 900 will taper (i.e., increase or decrease linearly) from one radial edge to an opposite radial edge of the upper surface 708 of the base portion 702.

In other examples, the mesas 900 can be machined to have a height tailored to tune a conductive heat transfer proximate to the mesas 900. The conductive heat transfer occurs between the upper surface 708 of the pedestal 700 and the substrate 212 through the mesas 900. For example, the mesas 900 of equal height can ensure consistent conductive heat transfer in the vicinity of the mesas 900. Alternatively, the mesas 900 can have a predetermined profile defined by the upper ends of the mesas 900. In some examples, thermal non-uniformities (e.g., caused by nonlinearities of the heater 110 shown in FIG. 1A) can be corrected by varying the height of the mesas 900.

A substrate 212 (shown in FIGS. 3-6) is arranged on the upper surface 708 of the base portion 702 of the pedestal 700 during processing. The substrate 212 rests on the seal band 710 and on the mesas 900. The OD of the substrate 212 is approximately equal to the OD of the seal band 710. The substrate 212 covers the seal band 710 (e.g., as shown in FIGS. 3-6). The curved shape provided by the mesas 900 to the upper portion 708 of the pedestal 700 improves the clamping force with which the substrate 212 is clamped to the pedestal 700 during processing. The mesas 900 improve both electrostatic and vacuum clamping of the substrate 212 to the upper surface 708 of the pedestal 700. In some examples, the substrate 212 may not be clamped to the upper portion 708 of the pedestal 700.

FIGS. 11A-12E show various configurations in which the mesas 900 can be arranged on the upper surface 708 of the pedestal 700. Specifically, the configurations include various combinations of concave (cup shaped) and convex (dome shaped) surfaces formed by the mesas 900 and the upper surface 708 of the pedestal 700 on which a substrate is arranged during processing. Briefly, FIG. 11A shows an arrangement of the mesas 900 on the upper surface 708 of the pedestal 700 that provide a flat surface on which the substrate is arranged during processing. FIGS. 11B-11F show various arrangements of the mesas 900 and the upper surface 708 of the pedestal 700 that include a concave upper surface 708 and/or a concave surface formed by the mesas 900 on which the substrate is arranged during processing. FIGS. 12A-12E show various arrangements of the mesas 900 and the upper surface 708 of the pedestal 700 that include a convex upper surface 708 and/or a convex surface formed by the mesas 900 on which the substrate is arranged during processing. These configurations are now described in detail.

In FIG. 11A, the upper surface 708 of the pedestal 700 is flat. That is, the upper surface 708 of the pedestal 700 is parallel to a plane of a substrate (e.g., the substrate 212 shown in FIGS. 3-6) that is arranged on the pedestal 700 during processing. For example, the upper surface 708 of the pedestal 700 has a roughness in the range of about 1 Ra to 64 Ra (Micro-inch). The mesas 900 are arranged on the upper surface 708 of the pedestal 700 such that the mesas 900 extend vertically upwards from the upper surface 708 of the pedestal 700. The mesas 900 are of equal height (or length). The top ends of the mesas 900 are flat and lie in a plane parallel to the plane of the upper surface 708 of the pedestal 700, which is parallel to the plane in which the substrate lies when arranged on the mesas 900 during processing.

In FIG. 11B, the upper surface 708 of the pedestal 700 is concave. The mesas 900 are arranged on the upper surface 708 of the pedestal 700 such that the mesas 900 extend vertically upwards from the upper surface 708 of the pedestal 700. The top ends of the mesas 900 are flat. A substrate is placed on the top ends of the mesas 900 during processing. The mesas 900 are of different height (or length). However, the top ends of the mesas 900 are aligned with each other and lie in a plane parallel to the plane in which the substrate lies when arranged on the mesas 900 during processing. Thus, while the upper surface 708 of the pedestal 700 is concave, the top ends of the mesas 900 provide a flat surface on which the substrate lies during processing. Due to the concave shape of the upper surface 708 of the pedestal 700 and since the top ends of the mesas 900 lie in a single plane, the height of the mesas 900 and consequently the distance between the substrate and the concave upper surface 708 of the pedestal 700 varies (decreases) from the center to the periphery of the concave upper surface 708 of the pedestal 700.

In FIG. 11C, the upper surface 708 of the pedestal 700 is flat as in FIG. 11A. The mesas 900 are arranged on the upper surface 708 of the pedestal 700 such that the mesas 900 extend vertically upwards from the upper surface 708 of the pedestal 700. The mesas 900 are of different lengths (i.e., height). The top ends of the mesas 900 are not aligned with each other and do not lie in a single plane parallel to the plane of the upper surface 708 of the pedestal 700. Instead, the top ends of the mesas 900 are concave and form a concave surface on which a cupped substrate can be placed during processing. Since the top ends of the mesas 900 form a concave surface, the distance between the substrate and the upper surface 708 of the pedestal 700 varies (increases) from the center to the periphery of the upper surface 708 of the pedestal 700.

FIGS. 11D-11F show different configurations of a concave upper surface 708 of the pedestal 700 and a concave surface formed by the top ends of the mesas 900. In FIGS. 11D-11F, R1 denotes a radius of the concave upper surface 708 of the pedestal 700, and R2 denotes a radius of the concave surface formed by the concave top ends of the mesas 900.

In FIG. 11D, R1=R2. The mesas 900 are of equal length (i.e., height). The top ends of the mesas 900 are concave. A cupped substrate is placed on the concave top ends of the mesas 900 during processing. Since the mesas 900 are of equal length and R1=R2, the distance between the concave upper surface 708 of the pedestal 700 and the cupped substrate is fixed (constant) from the center to the periphery of the concave upper surface 708 of the pedestal 700. That is, the gap between the cupped substrate and the concave upper surface 708 of the pedestal 700 is fixed (constant) from the center to the periphery of the concave upper surface 708 of the pedestal 700.

In FIG. 11E, R2<R1. The height (i.e., length) of the mesas 900 varies (increases) from the center to the periphery of the concave upper surface 708 of the pedestal 700. The top ends of the mesas 900 are concave. A cupped substrate is placed on the concave top ends of the mesas 900 during processing. Since the height of the mesas 900 increases from the center to the periphery of the concave upper surface 708 of the pedestal 700 and R2<R1, the distance between the concave upper surface 708 of the pedestal 700 and the cupped substrate varies (increases) from the center to the periphery of the concave upper surface 708 of the pedestal 700. That is, the gap between the cupped substrate and the concave upper surface 708 of the pedestal 700 varies (increases) from the center to the periphery of the concave upper surface 708 of the pedestal 700.

In FIG. 11F, R2>R1. The height (i.e., length) of the mesas 900 varies (decreases) from the center to the periphery of the concave upper surface 708 of the pedestal 700. The top ends of the mesas 900 are concave. A cupped substrate is placed on the concave top ends of the mesas 900 during processing. Since the height of the mesas 900 decreases from the center to the periphery of the concave upper surface 708 of the pedestal 700 and R2>R1, the distance between the concave upper surface 708 of the pedestal 700 and the cupped substrate varies (decreases) from the center to the periphery of the concave upper surface 708 of the pedestal 700. That is, the gap between the cupped substrate and the concave upper surface 708 of the pedestal 700 varies (decreases) from the center to the periphery of the concave upper surface 708 of the pedestal 700.

These configurations provide various advantages. Below are some non-limiting examples of the advantages. For example, some of these configurations improve the clamping of the substrate to the pedestal 700. Cupping the top surfaces of the mesas 900 (i.e., by making the top surfaces of the mesas 900 concave) allows a cupped substrate to sit lower (i.e., be closer to the upper surface 708 of the pedestal 700). In some of the configurations (e.g., in FIGS. 11D and 11F), cupping the top surfaces of the mesas 900 can result in a relatively small gap between the cupped substrate and the upper surface 708 of the pedestal 700 at the edge of the pedestal 700, which allows creating an improved pressure gradient in the vacuum clamping system used to clamp the cupped substrate to the pedestal 700. Clamping can be most effective when R1=R2 (FIG. 11D).

Additionally, the configuration with R1=R2 also provides uniform heat transfer from the pedestal 700 to the substrate as a function of radius. The configuration with R2<R1 (FIG. 11E) can help improve clamping, and any issues with thermal uniformity (i.e., uniform heat transfer from the pedestal 700 to the substrate as a function of radius) can be corrected or improved by the varying the gap between the substrate and the upper surface 708 of the pedestal 700. The top to bottom height of a mesa 900 defines the localized gap. The gap between the substrate and the upper surface 708 of the pedestal 700 can be varied by varying the height of the mesas 900 while maintaining R2<R1. The configuration shown in FIG. 11B may not help with clamping but can be useful in correcting/improving thermal uniformity. Many other advantages are contemplated.

FIGS. 12A-12D show additional configurations in which the mesas 900 can be arranged on the upper surface 708 of the pedestal 700. In FIG. 12A, the upper surface 708 of the pedestal 700 is convex. The mesas 900 are arranged on the upper surface 708 of the pedestal 700 such that the mesas 900 extend vertically upwards from the upper surface 708 of the pedestal 700. The top ends of the mesas 900 are flat. A substrate is placed on the top ends of the mesas 900 during processing. The mesas 900 are of different lengths. However, the top ends of the mesas 900 are aligned with each other and lie in a plane parallel to the plane of the upper surface 708 of the pedestal 700, which is also parallel to the plane in which the substrate lies on the mesas 900. Thus, while the upper surface 708 of the pedestal 700 is convex, the top ends of the mesas 900 provide a flat surface on which the substrate lies. Due to the convex shape of the upper surface 708 of the pedestal 700 and since the top ends of the mesas 900 lie in a single plane, the height of the mesas 900 and consequently the distance between the substrate and the convex upper surface 708 of the pedestal 700 varies (increases) from the center to the periphery of the convex upper surface 708 of the pedestal 700.

In FIG. 12B, the upper surface 708 of the pedestal 700 is flat as in FIG. 11A. The mesas 900 are arranged on the upper surface 708 of the pedestal 700 such that the mesas 900 extend vertically upwards from the upper surface 708 of the pedestal 700. The mesas 900 are of different lengths (i.e., height). The top ends of the mesas 900 are not aligned with each other and do not lie in a single plane parallel to the plane of the upper surface 708 of the pedestal 700. Instead, the top ends of the mesas 900 form a convex surface or a dome shape on which a domed substrate can be placed during processing. The bottom ends of the mesas 900 are flat. Since the top ends of the mesas 900 form a convex surface, the distance between the substrate and the upper surface 708 of the pedestal 700 varies (decreases) from the center to the periphery of the upper surface 708 of the pedestal 700.

FIGS. 12C-12E show different configurations of a convex shape of the upper surface 708 of the pedestal 700 and a convex surface formed by the top ends of the mesas 900. In FIGS. 12C-12E, R1 denotes a radius of the convex upper surface 708 of the pedestal 700, and R2 denotes a radius of the convex surface formed by the convex top ends of the mesas 900.

In FIG. 12C, R1=R2. The mesas 900 are of equal length (i.e., height). The top ends of the mesas 900 are convex. A domed substrate is placed on the convex top ends of the mesas 900 during processing. Since the mesas 900 are of equal length and R1=R2, the distance between the convex upper surface 708 of the pedestal 700 and the domed substrate is fixed (constant) from the center to the periphery of the convex upper surface 708 of the pedestal 700. That is, the gap between the domed substrate and the convex upper surface 708 of the pedestal 700 is fixed (constant) from the center to the periphery of the convex upper surface 708 of the pedestal 700.

In FIG. 12D, R2<R1. The height (length) of the mesas 900 varies (decreases) from the center to the periphery of the convex upper surface 708 of the pedestal 700. The top ends of the mesas 900 are convex. A domed substrate is placed on the convex top ends of the mesas 900 during processing. Since the height of the mesas 900 decreases from the center to the periphery of the convex upper surface 708 of the pedestal 700 and R2<R1, the distance between the convex upper surface 708 of the pedestal 700 and the domed substrate varies (decreases) from the center to the periphery of the convex upper surface 708 of the pedestal 700. That is, the gap between the domed substrate and the convex upper surface 708 of the pedestal 700 varies (decreases) from the center to the periphery of the convex upper surface 708 of the pedestal 700.

In FIG. 12E, R2>R1. The height (length) of the mesas 900 varies (increases) from the center to the periphery of the convex upper surface 708 of the pedestal 700. The top ends of the mesas 900 are convex. A domed substrate is placed on the convex top ends of the mesas 900 during processing. Since the height of the mesas 900 increases from the center to the periphery of the convex upper surface 708 of the pedestal 700 and R2>R1, the distance between the convex upper surface 708 of the pedestal 700 and the domed substrate varies (increases) from the center to the periphery of the convex upper surface 708 of the pedestal 700. That is, the gap between the domed substrate and the convex upper surface 708 of the pedestal 700 varies (increases) from the center to the periphery of the convex upper surface 708 of the pedestal 700.

These convex configurations provide advantages similar to those mentioned above for the concave configurations except that the thermal uniformity is reversed (i.e., there is an inversion in thermal uniformity in the convex configurations relative to the concave configurations). The domed wafers are inherently easy to clamp because they naturally make a good edge seal. However, the convex configurations can impact the thermal uniformity as follows. In general, areas of a substrate with smaller gaps between the substrate and the upper surface 708 of the pedestal 700 can be hotter than areas of the substrate with larger gaps between the substrate and the upper surface 708 of the pedestal 700. In configurations with a varying gap between the substrate and the upper surface 708 of the pedestal 700, the thermal uniformity can correspondingly vary proportional to the varying gap. Many additional advantages are contemplated.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, dielectric, insulator, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A pedestal comprising:
a base portion to support a substrate, the base portion being disc shaped and having an annular recess on an upper surface of the base portion along an outer diameter of the base portion;
a stem portion connected to the base portion;
a heat shield arranged below a lower surface of the base portion, the heat shield and the lower surface defining a manifold that is in fluid communication with a gas inlet; and
an edge ring including:
a cylindrical portion surrounding the base portion and having a first end resting on an outer edge of the heat shield and a second end, an inner surface of the cylindrical portion and an outer surface of the base portion defining a first gap in fluid communication with the manifold; and
an annular portion extending radially inwards over the annular recess from the second end of the cylindrical portion, the annular portion and the annular recess defining a second gap in fluid communication with the first gap;
wherein a purge gas supplied to the gas inlet flows through the manifold, the first and second gaps, and radially outwards over the annular portion.

2. The pedestal of claim 1 wherein the purge gas is supplied to the gas inlet while a material is deposited from a showerhead on a showerhead-facing surface of the substrate, and wherein the purge gas prevents the material from depositing on a pedestal-facing surface of the substrate.

3. The pedestal of claim 1 further comprising an electrostatic clamping system to clamp the substrate to the upper surface of the base portion.

4. The pedestal of claim 1 further comprising a vacuum clamping system to clamp the substrate to the upper surface of the base portion.

5. The pedestal of claim 1 wherein the upper surface of the base portion lies in a higher plane at an outer diameter of the base portion than at a center of the base portion.

6. The pedestal of claim 1 wherein the upper surface of the base portion lies in a lower plane at an outer diameter of the base portion than at a center of the base portion.

7. The pedestal of claim 1 further comprising an annular sealing band arranged on the upper surface of the base portion wherein an outer diameter of the annular sealing band is equal to an inner diameter of the annular recess and an outer diameter of the substrate.

8. The pedestal of claim 1 further comprising an actuator configured to move the pedestal vertically relative to a showerhead to adjust a gap between the substrate and the showerhead during processing.

9. The pedestal of claim 1 wherein an upper surface of the annular portion lies in a higher plane than a showerhead-facing surface of the substrate.

10. The pedestal of claim 1 wherein each of upper and lower surfaces of the annular portion includes a radially outer portion and a radially inner portion, wherein the radially outer portions extend parallel to the annular recess from the cylindrical portion, and wherein the radially inner portions slope towards an inner diameter of the annular portion.

11. The pedestal of claim 1 wherein the cylindrical portion is parallel to the outer surface of the base portion and wherein the annular portion is parallel to the annular recess.

12. The pedestal of claim 1 wherein outer diameters of the cylindrical and annular portions are equal.

13. The pedestal of claim 1 wherein an inner diameter of the annular recess is greater than or equal to an outer diameter of the substrate.

14. The pedestal of claim 1 wherein an inner diameter of the annular portion is greater than an inner diameter of the annular recess and an outer diameter of the substrate.

15. The pedestal of claim 1 wherein an upper surface of the annular portion is level with a showerhead-facing surface of the substrate and wherein a lower surface of the annular portion extends parallel to the annular recess from the cylindrical portion and slopes upwards towards an inner diameter of the annular portion.

16. The pedestal of claim 15 further comprising a second ring arranged at a distance above the upper surface of the annular portion wherein inner and outer diameters of the second ring are equal to respective diameters of the annular portion and wherein upper and lower surfaces of the second ring are parallel to the upper surface of the annular portion.

17. The pedestal of claim 1 wherein the annular portion includes a plurality of holes extending radially outwards from an inner diameter of the annular portion.

18. The pedestal of claim 1 wherein:
a lower surface of the annular portion extends parallel to the annular recess from the cylindrical portion and slopes upwards towards an inner diameter of the annular portion; and
an upper surface of the annular portion includes a first portion that slopes upwards from the inner diameter of the annular portion for a first distance and a second portion that slopes downwards towards from the first distance to an outer diameter of the annular portion, and includes a plurality of holes extending radially through the first portion and partially through second portion.

19. A system comprising the pedestal of claim 1 and a controller to control flow of the purge gas through the gas inlet.

20. The pedestal of claim 1 wherein the gas inlet is located at a bottom of the stem portion.

21. A pedestal to support a substrate, the pedestal comprising:
a base portion having a disc shape and including:
an annular ridge on an upper surface, the annular ridge having an outer diameter less than an outer diameter of the base portion and having an inner diameter greater than or equal to an outer diameter of the substrate;
an annular protrusion on a lower surface, the annular protrusion having a diameter less than the inner diameter of the annular ridge and the outer diameter of the substrate; and
a plurality of holes extending outwardly from the lower surface to the upper surface, the holes arranged along a first circle on the upper surface and along a second circle on the lower surface, the first circle having a first diameter that is less than the inner diameter of the annular ridge and the outer diameter of the substrate and greater than the diameter of the annular protrusion, and the second circle having a second diameter that is less than the diameter of the annular protrusion; and
a stem portion extending from the base portion.

22. The pedestal of claim 21 further comprising:
a heat shield arranged parallel to and below the lower surface of the base portion, the heat shield being connected to the annular protrusion, wherein the heat shield, the lower surface, and the annular protrusion define a manifold that is in fluid communication with a gas inlet,
wherein a purge gas supplied to the gas inlet while a material is deposited on the substrate flows through the manifold and the holes, flows radially outwards over the annular ridge, and prevents the material from depositing on a pedestal-facing surface of the substrate.

23. The pedestal of claim 21 further comprising an electrostatic clamping system or a vacuum clamping system to clamp the substrate to the upper surface of the base portion.

24. The pedestal of claim 21 wherein the annular ridge ascends vertically from the upper surface of the base portion at the inner diameter of the annular ridge, extends outwards at an angle relative to a vertical axis of the stem portion, extends radially outwards, and descends vertically to the upper surface of the base portion at the outer diameter of the annular ridge.

25. The pedestal of claim 21 wherein the holes extend from the lower surface to the upper surface at an acute angle relative to a vertical axis of the stem portion.

26. The pedestal of claim 21 further comprising an annular sealing band arranged on the upper surface of the base portion wherein an outer diameter of the annular sealing band is less than the first diameter of the first circle.

27. The pedestal of claim 21 further comprising an actuator configured to move the pedestal vertically relative to a showerhead to adjust a gap between the substrate and the showerhead during processing.

28. A system comprising the pedestal of claim 22 and a controller to control flow of the purge gas through the gas inlet.

29. The pedestal of claim 22 wherein the gas inlet is located at a bottom of the stem portion.

30. The pedestal of claim 22 further comprising a ring arranged around the pedestal, the ring including:
a cylindrical portion surrounding the base portion and having a first end aligned with an outer edge of the heat shield and a second end; and
an annular portion extending radially inwards from the second end over the upper surface of the base portion to the outer diameter of the annular ridge,
wherein upper surfaces of the annular ridge and the annular portion of the ring are coplanar.

31. A pedestal assembly comprising:
a pedestal including:
a base plate having a first surface and a second surface opposite the first surface; and
a stem extending from the second surface of the base plate,
wherein a plurality of through holes extend from the first surface through the second surface of the base plate at a location radially outside of the stem;
a collar arranged around the stem and the plurality of through holes, wherein the collar defines a first annular volume between an inner surface of the collar and an outer surface of the stem, and wherein an upper surface of the collar forms a surface-to-surface seal with the second surface of the base plate; and
an annular heat shield having a first portion arranged below the second surface of the base plate and having a second portion extending from a radially inner end of the first portion, wherein the second portion surrounds the collar and defines a second annular volume between an inner surface of the second portion of the annular heat shield and an outer surface of the collar.

32. The pedestal assembly of claim 31 wherein the first annular volume is separate from the second annular volume.

33. The pedestal assembly of claim 31 wherein one or more gases are suctioned out from under a substrate placed on the base plate via the plurality of through holes and the first annular volume to clamp the substrate to the base plate.

34. The pedestal assembly of claim 31 wherein a purge gas is injected into the second annular volume to egress around edges of a substrate placed on the base plate during processing.

35. The pedestal assembly of claim 34 wherein the purge gas prevents deposition on a pedestal-facing surface of the substrate.

36. The pedestal assembly of claim 31 further comprising:
an edge ring surrounding the base plate;
wherein a bottom surface of the edge ring forms a surface-to-surface seal with an upper surface of the first portion of the annular heat shield;
wherein the upper surface of the first portion of the annular heat shield, an inner side surface of the edge ring, and the second surface of the base plate define a manifold that is in fluid communication with the second annular volume; and
wherein a purge gas is injected into the second annular volume to egress through a gap between the edge ring and the base plate.

37. The pedestal assembly of claim 36 wherein the purge gas prevents deposition on a pedestal-facing surface of a substrate arranged on the base plate.

38. The pedestal assembly of claim 31 wherein a bottom end of the stem of the pedestal includes a flange extending radially outwardly, the pedestal assembly further comprising a pedestal support structure attached to the flange with an O-ring disposed between the flange and the pedestal support structure.

39. The pedestal assembly of claim 38 wherein the pedestal support structure includes a cylindrical body with a side wall, a vertical bore in the side wall defines a gas channel, and the gas channel fluidly communicates with the first annular volume and the plurality of through holes.

40. The pedestal assembly of claim 38 wherein the pedestal support structure includes a cylindrical body with a side wall, a bore in the side wall defines a gas channel, and the gas channel fluidly communicates with the second annular volume.

41. The pedestal assembly of claim 38 wherein the pedestal support structure includes a cylindrical body defining an inner cavity and includes a second flange extending radially outwardly from an upper surface of the cylindrical body, the pedestal assembly further comprising one or more clamps connecting the flange at the bottom end of the stem to the second flange of the pedestal support structure.

42. The pedestal assembly of claim 38 wherein the pedestal support structure includes a cylindrical body defining an inner cavity and includes a second flange extending radially outwardly from an upper surface of the cylindrical body, the pedestal assembly further comprising a clamp having an L-shaped cross-section, wherein the second flange rests on a horizontal portion of the clamp forming a surface-to-surface seal therewith.

43. The pedestal assembly of claim 42 wherein an upper end of a vertical portion of the clamp includes a third flange extending radially outwardly and includes first and second vertical portions respectively extending from radially outer and inner ends on an upper surface of the third flange.

44. The pedestal assembly of claim 43 wherein a bottom end of the collar forms a first surface-to-surface seal with the second vertical portion, and wherein a bottom end of the second portion of the annular heat shield forms a second surface-to-surface seal with the first vertical portion.

45. The pedestal assembly of claim 44 wherein the first and second surface-to-surface seals prevent fluid communication between the first and second annular volumes.

46. The pedestal assembly of claim 44 wherein the cylindrical body includes a vertical portion extending upwards from the second flange and wherein a radially inner portion of the upper end of the vertical portion of the clamp forms a surface-to-surface seal with a radially outer surface of an upper end of the vertical portion of the cylindrical body.

47. The pedestal assembly of claim 46 wherein:
the cylindrical body has a side wall having a first bore therein;
the vertical portion of the clamp is spaced from the vertical portion of the cylindrical body extending upwards from the second flange defining a cavity that is in fluid communication with the first bore; and
the upper end of the vertical portion of the clamp includes a second bore that is in fluid communication with the cavity and the second annular volume.

48. The pedestal assembly of claim 39, further comprising:
a valve configured to selectively connect the gas channel, the first annular volume, and the plurality of through holes to a vacuum pump; and
a controller configured to selectively control the valve to remove one or more gases from under a substrate arranged on the base plate via the gas channel, the first annular volume, and the plurality of through holes to clamp the substrate to the base plate during processing of the substrate.

49. The pedestal assembly of claim 40, further comprising:
a valve configured to selectively connect the gas channel and the second annular volume to a source of a purge gas; and
a controller configured to selectively control the valve to supply the purge gas through the gas channel and the second annular volume during processing of a substrate arranged on the base plate to prevent deposition on a pedestal facing side of the substrate.

50. The pedestal assembly of claim 31, further comprising:
an annular seal band disposed on the first surface of the base plate along an outer diameter of the first surface; and
a plurality of projections extending upwards from the first surface of the base plate, wherein the projections are distributed from a center of the first surface to an inner diameter of the annular seal band.

51. The pedestal assembly of claim 50 wherein a height of the projections decreases from the inner diameter of the annular seal band to the center of the first surface of the base plate.

52. The pedestal assembly of claim 50 wherein a height of the projections increases from the inner diameter of the annular seal band to the center of the first surface of the base plate.

53. A pedestal assembly comprising:
a pedestal including a base plate and a stem extending from the base plate, the base plate being disc shaped and having an upper surface;
a plurality of projections extending upwards from the upper surface of the base plate and distributed from a center of the upper surface of the base plate to an outer diameter of the pedestal,
wherein the projections have a height tailored to tune a conductive heat transfer proximate to the projections.

54. The pedestal assembly of claim 53 wherein the projections have a profile defined by upper ends of the projections.

55. The pedestal assembly of claim 53 wherein the projections have equal height.

56. The pedestal assembly of claim 53 wherein a first set of the projections has a different height than a second set of the projections.

57. The pedestal assembly of claim 53 wherein a height of the projections decreases from the inner diameter of the annular seal band to the center of the upper surface of the base plate.

58. The pedestal assembly of claim 53 wherein a height of the projections increases from the inner diameter of the annular seal band to the center of the upper surface of the base plate.

59. The pedestal assembly of claim 53 wherein the projections are cylindrical.

60. The pedestal assembly of claim 53 further comprising an electrostatic clamping system disposed in the pedestal to clamp a substrate to the upper surface of the base plate.

61. The pedestal assembly of claim 53 further comprising a vacuum clamping system disposed in the pedestal to clamp a substrate to the upper surface of the base plate.

62. The pedestal assembly of claim 53 wherein a substrate is not clamped to the upper surface of the base plate.

63. The pedestal assembly of claim 53 wherein a height of the projections changes linearly from one radial edge to an opposite radial edge of the upper surface of the base plate.

64. The pedestal assembly of claim 53 wherein the upper surface of the base plate including the projections is concave.

65. The pedestal assembly of claim 53 wherein the upper surface of the base plate including the projections is convex.

66. A pedestal assembly comprising:
a pedestal including a base plate and a stem extending from the base plate, the base plate being disc shaped and having an upper surface that is concave;
a plurality of projections extending upwards from the upper surface of the base plate and distributed from a center of the upper surface of the base plate to an outer diameter of the pedestal,
wherein the projections have top ends that are concave.

67. The pedestal assembly of claim 66 wherein radii of curvature of the upper surface of the pedestal and the top ends of the projections are equal.

68. The pedestal assembly of claim 66 wherein radii of curvature of the upper surface of the pedestal and the top ends of the projections are different.

69. The pedestal assembly of claim 66 wherein a first radius of curvature of the upper surface of the pedestal is greater than a second radius of curvature of the top ends of the projections.

70. The pedestal assembly of claim 66 wherein a first radius of curvature of the upper surface of the pedestal is less than a second radius of curvature of the top ends of the projections.

71. A pedestal assembly comprising:
a pedestal including a base plate and a stem extending from the base plate, the base plate being disc shaped and having an upper surface that is convex;
a plurality of projections extending upwards from the upper surface of the base plate and distributed from a center of the upper surface of the base plate to an outer diameter of the pedestal,
wherein the projections have top ends that are convex.

72. The pedestal assembly of claim 71 wherein radii of curvature of the upper surface of the pedestal and the top ends of the projections are equal.

73. The pedestal assembly of claim 71 wherein radii of curvature of the upper surface of the pedestal and the top ends of the projections are different.

74. The pedestal assembly of claim 71 wherein a first radius of curvature of the upper surface of the pedestal is greater than a second radius of curvature of the top ends of the projections.

75. The pedestal assembly of claim 71 wherein a first radius of curvature of the upper surface of the pedestal is less than a second radius of curvature of the top ends of the projections.
